(19) United States
(12) Patent Application Publication
(10) Pub. No.: US 2026/0324413 A1
(43) Pub. Date: Oct. 15, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Cheng-Ying HO, Tainan (TW); Wen-De WANG, Tainan (TW); Kai-Chun HSU, Tainan (TW); Jen-Cheng LIU, Hsin-Chu City (TW)

(21) Appl. No.: 19/175,670

(22) Filed: Apr. 10, 2025

(51) Int. Cl. H01L 23/522; H10D 1/00; H10D 1/68; H10F 39/18

(52) U.S. Cl. CPC H10W 20/496; H10D 1/042; H10D 1/714; H10D 1/716; H10F 39/18

(57) ABSTRACT

The top electrode layers of multiple capacitor structures are commonly connected to the same interconnect structure (e.g., via) for the supply of voltage to each top electrode layer. The commonly connected top electrode layers require a smaller quantity of metallization structures and interconnect structures for signal routing, which occupy a smaller area of a semiconductor device in comparison to metallization structures and interconnect structures for individually connected top electrode layers. As a result, larger metal-insulator-metal (MIM) capacitor structures may be formed, resulting in larger capacitor storage capacity, and increased device performance.

### BACKGROUND

A capacitor structure, such as a deep trench capacitor (DTC) structure, may include a metal-insulator-metal (MIM) structure in which an insulator layer is sandwiched between two conductive electrode layers. Various types of semiconductor devices may include one or more capacitor structures, such as an image sensor device, a memory device (e.g., a dynamic random access memory (DRAM) device), a logic device, a processor, a system on chip (SoC), and/or an integrated passive device (IPD), among other examples. A capacitor structure may be included in an interconnect layer of a semiconductor device. The capacitor structure may extend through a plurality of dielectric layers in the interconnect layer and may be electrically coupled to one or more conductive structures in the interconnect layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of example circuits for a pixel sensor described herein.

FIGS. 2A and 2B are diagrams of an example semiconductor device described herein.

FIGS. 3A-3L are diagrams of an example implementation of forming a semiconductor device described herein.

FIG. 4 is a diagram of an example implementation of an arrangement of capacitor structures described herein.

FIG. 5 is a diagram of an example implementation of an arrangement of capacitor structures described herein.

FIG. 6 is a diagram of an example semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A complementary metal oxide semiconductor (CMOS) image sensor device may include a plurality of pixel sensors arranged in a pixel sensor array. A pixel sensor of the CMOS image sensor device may include a photodiode configured to convert photons of incident light to a photocurrent of electrons. The magnitude of the photocurrent is based at least in part on the intensity of the incident light.

In addition to a photodiode (e.g., a sensing region), a pixel sensor of an image sensor device (e.g., a complementary metal-oxide-semiconductor (CMOS) image sensor) may also include a control circuitry region. The control circuitry region is electrically connected to the photodiode and is configured to receive a photocurrent that is generated by the photodiode and to store the photocurrent in a floating diffusion node. The photocurrent in the floating diffusion node may be sampled and converted to a pixel sensor signal that can be used to generate an image and/or a video.

The pixel sensor may be a lateral overflow integration capacitor (LOFIC) pixel sensor that includes an overflow gate and an overflow capacitor. The overflow capacitor may be electrically coupled to the floating diffusion node through the overflow gate such that photocurrent may be transferred from the floating diffusion node to the overflow capacitor for temporary storage. The overflow gate may selectively control the flow of photocurrent to and/or from the overflow capacitor. This enables additional photocurrent to be transferred to the floating diffusion node from the photodiode without causing the pixel sensor to reach saturation, which increases the full well capacity (FWC) and the dynamic range of the pixel sensor.

Additionally or alternatively, the pixel sensor may be a voltage domain global shutter (VDGS) pixel sensor, which stores and reads out pixel data based on voltage levels within a pixel itself. As a result, instead of capturing portions of an image at different times, a “global shutter” functionality can be implemented where an entire image may be captured at a particular time. A VDGS pixel sensor may accurately capture fast-moving objects.

Increasing the storage capacity of capacitors used in LOFIC and/or VDGS pixel sensors may increase device performance. The capacitance of the capacitor structure (e.g., the amount of charge that can be stored by the capacitor structure) is directly dependent on the geometry of the conductive electrode layers of the capacitor structure. However, decreases in the space between adjacent pixels (e.g., pitch) result in smaller areas in which metal-insulator-metal (MIM) capacitors may be formed. The top electrode layers of respective capacitor structures may be individually connected to interconnect structures (e.g., vias) for the supply of voltage to each top electrode layer, even when the voltage for the top electrode layers for the respective capacitor structures may be the same. The individually connected top electrode layers may require extra metallization structures and interconnect structures for signal routing, which further occupy an already diminished area of the device. As a result, smaller MIM capacitor structures may be formed, resulting in smaller capacitor storage capacity, and decreased device performance.

In some implementations, the top electrode layers of multiple capacitor structures are commonly connected to the same interconnect structure (e.g., via) for the supply of voltage to each top electrode layer. The commonly connected top electrode layers require a smaller quantity of metallization structures and interconnect structures for signal routing, which occupy a smaller area of a semiconductor device in comparison to metallization structures and interconnect structures for individually connected top electrode layers. As a result, larger MIM capacitor structures may be formed, resulting in larger capacitor storage capacity, and increased device performance.

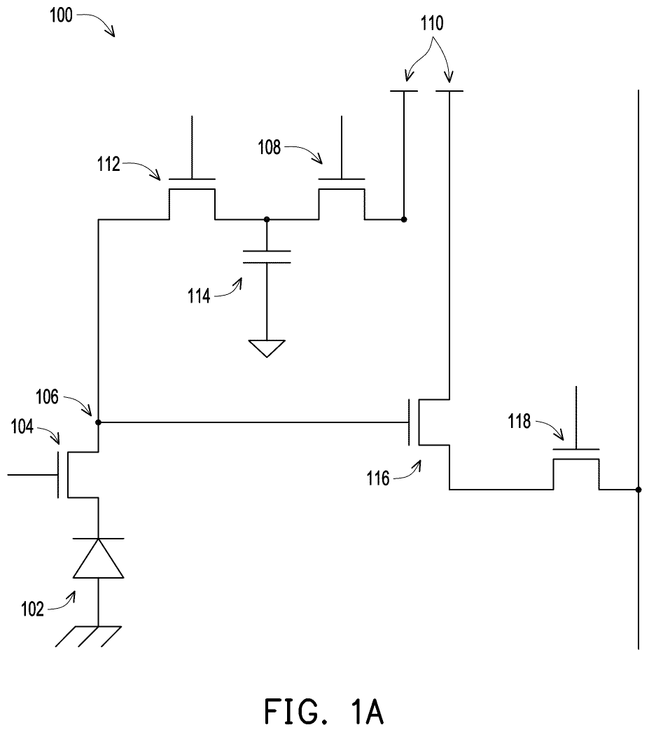

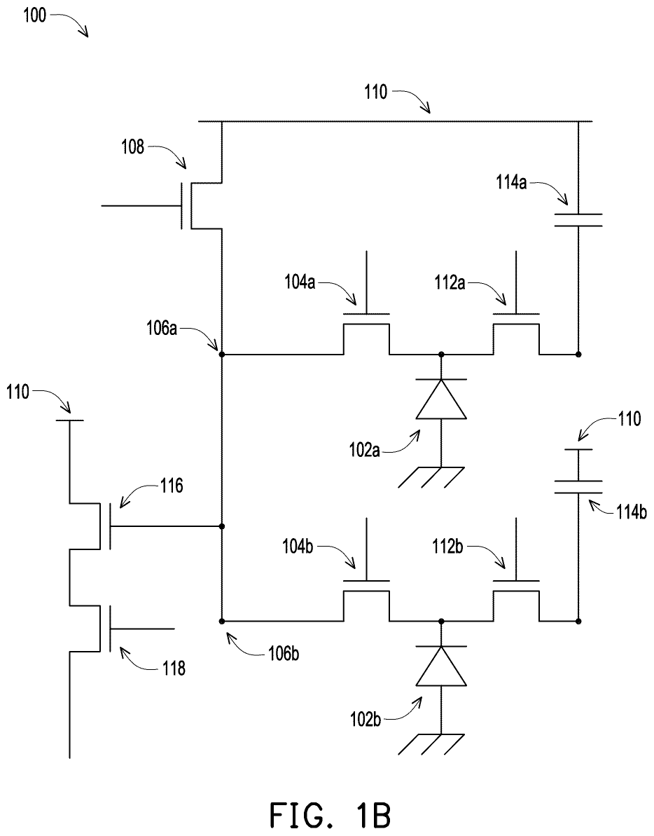

FIGS. 1A and 1B are diagrams of example circuits for a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

As shown in an example circuit in FIG. 1A, a pixel sensor 100 includes a photodiode 102 that may be configured to sense and/or accumulate incident light (e.g., light directed toward the pixel sensor 100) and convert photons of the incident light to a photocurrent. The magnitude of the photocurrent may be based on the number of photons (e.g., the intensity of the incident light) collected in the photodiode 102. Thus, the accumulation of photons in the photodiode 102 generates a build-up of electrical charge that represents the intensity or brightness of the incident light (e.g., a greater amount of charge may correspond to a greater intensity or brightness, and a lesser amount of charge may correspond to a lower intensity or brightness).

The photodiode 102 is electrically connected to a transfer gate 104. The transfer gate 104 is configured to control the transfer of the photocurrent from the photodiode to a floating diffusion node 106. The transfer gate 104 may be selectively switched by applying a transfer voltage (Vₜₓ) to the transfer gate 104. In some implementations, the transfer voltage being applied to the transfer gate 104 causes a leakage path (e.g., a buried channel) to form between the photodiode 102 and the floating diffusion node 106 across the transfer gate 104, which enables the photocurrent to travel along the leakage path to the floating diffusion node 106. In some implementations, the transfer voltage being removed from the transfer gate 104 (or the absence of the transfer voltage) causes the leakage path to be removed, such that the photocurrent cannot pass from the photodiode 102 to the floating diffusion node 106.

The circuit for the pixel sensor 100 may further include a reset gate 108. The reset gate 108 is electrically connected to a voltage source 110. The reset gate 108 may be controlled to selectively apply a reset voltage (Vᵣₛₜ) to the floating diffusion node 106 from the voltage source 110. The transfer gate 104 and the reset gate 108 may be electrically coupled to the floating diffusion node 106 such that the reset voltage is applied to the floating diffusion node 106 to “reset” the floating diffusion node 106 (e.g., by draining any residual charge in the floating diffusion node 106) prior to activation of the transfer gate 104 to transfer a photocurrent from the photodiode 102 to the floating diffusion node 106.

The pixel sensor 100 may be a lateral overflow integration capacitor (LOFIC) pixel sensor that includes an overflow gate 112 and an overflow capacitor 114. The overflow capacitor 114 may be electrically coupled to the floating diffusion node 106 through the overflow gate 112 such that photocurrent may be transferred from the floating diffusion node 106 to the overflow capacitor 114 for temporary storage. The overflow gate 112 may selectively control the flow of photocurrent to and/or from the overflow capacitor 114. This enables additional photocurrent to be transferred to the floating diffusion node 106 from the photodiode 102 without causing the pixel sensor 100 to reach saturation, which increases the full well capacity and the dynamic range of the pixel sensor 100.

The photocurrent may be used to apply a floating diffusion voltage (V_{fd}) to a source follower gate 116 of the circuit of the pixel sensor 100. This permits the photocurrent to be observed without removing or discharging the photocurrent from the floating diffusion node 106 and/or from the overflow capacitor 114. The reset gate 108 may instead be used to remove or discharge the photocurrent from the floating diffusion node 106 and/or from the overflow capacitor 114.

To apply the floating diffusion voltage to the source follower gate 116, the transfer gate 104 may be switched off (e.g., so that the photocurrent does not flow back into the photodiode 102) and the overflow gate 112 may be switched on. This configuration enables the photocurrent stored in floating diffusion node 106 and in the overflow capacitor 114 to be used to apply the floating diffusion voltage to the source follower gate 116.

The source follower gate 116 functions as a high impedance amplifier for the pixel sensor 100. The source follower gate 116 provides a voltage-to-current conversion of the floating diffusion voltage. The output of the source follower gate 116 is electrically connected to a row select gate 118, which is configured to control the flow of the photocurrent to external circuitry. The row select gate 118 is controlled by selectively applying a select voltage (V_{di}) to the gate of the row select gate 118. This permits the photocurrent to flow to an output of the pixel sensor 100.

As shown in another example circuit in FIG. 1B, a pixel sensor 100 may include a plurality of subcircuits. The subcircuits may include a small pixel subcircuit and a large pixel subcircuit. The small pixel subcircuit may include a small photodiode 102a, a transfer gate 104a, a floating diffusion node 106a, an overflow gate 112a, and an overflow capacitor 114a. The large pixel sensor subcircuit may include a large photodiode 102b, a transfer gate 104b, a floating diffusion node 106b, an overflow gate 112b, and an overflow capacitor 114b. The small pixel subcircuit and the large pixel subcircuit may both be connected to the reset gate 108, the voltage source 110, the source follower gate 116, and the row select gate 118. The large photodiode 102b may be physically larger than the small photodiode 102a, thereby enabling pixel sensor 100 to have different regions of photonic sensitivity.

As indicated above, FIGS. 1A and 1B are provided as examples. Other examples may differ from what is described with regard to FIGS. 1A and 1B.

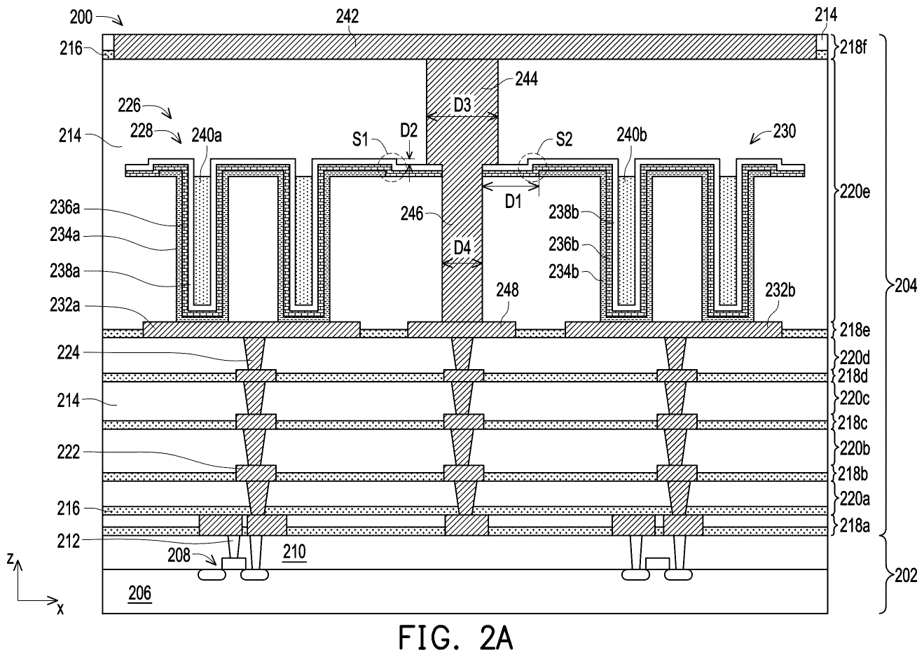

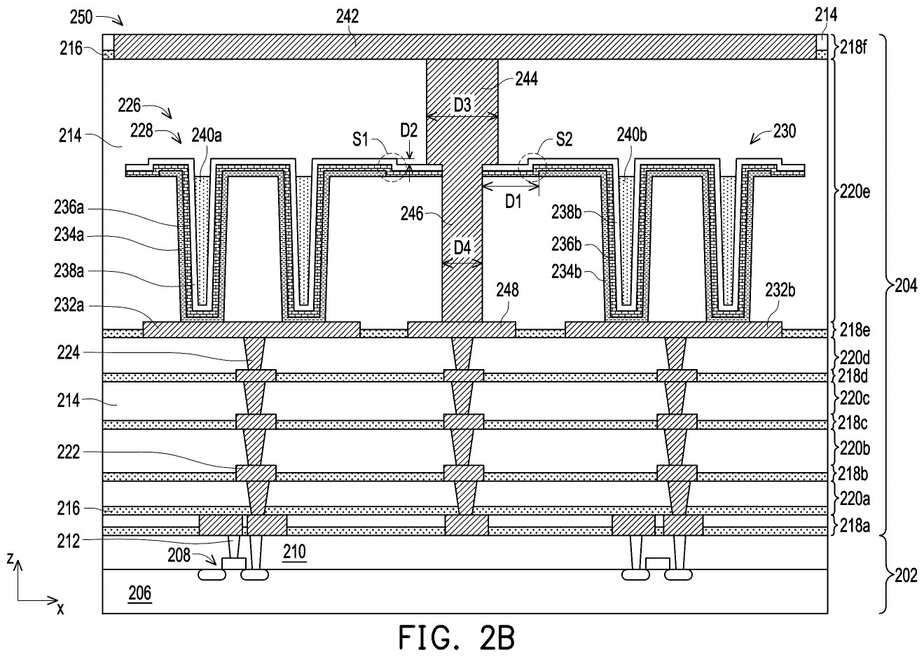

FIG. 2A is a diagram of an example semiconductor device 200 described herein. The semiconductor device 200 may include a system-on-chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device. In the case of an image sensor device, the semiconductor device 200 may include an example structural implementation of an overflow capacitor 114 of a pixel sensor 100 described herein.

FIG. 2A illustrates a cross-section view of the semiconductor device 200. As shown in FIG. 2A, the semiconductor device 200 may include a device layer 202 and an interconnect layer 204 arranged in a z-direction in the semiconductor device 200 with respect to the device layer 202. For example, the interconnect layer 204 (e.g., interconnect structure) may be located above the device layer 202. As another example, the interconnect layer 204 may be located below the device layer 202.

The interconnect layer 204 may include conductive structures that are arranged to carry signals and/or provide power distribution throughout the semiconductor device 200. In some implementations, the semiconductor device 200 includes interconnect layers 204 above and below the device layer 202. A first interconnect layer 204 on a first side of the device layer 202 may be used for signal propagation throughout the semiconductor device 200, and a second interconnect layer 204 on an opposing second side of the device layer 202 may be used for power distribution in the semiconductor device 200.

The device layer 202 includes a substrate 206 of the semiconductor device 200. The substrate 206 may correspond to a portion of a semiconductor wafer on which the semiconductor device 200 is formed. The substrate 206 may include a silicon (Si) substrate, a substrate formed of a material including silicon, a III-V compound semiconductor material substrate such as gallium arsenide (GaAs), a silicon-on-insulator (SOI) substrate, or another type of substrate. The substrate 206 may extend in an x-direction and/or in a y-direction in the semiconductor device 200 such that the top and bottom surfaces of the substrate 206 are approximately orthogonal to the z-direction in the semiconductor device 200.

Integrated circuit devices 208 may be included in and/or on the substrate 206 in the device layer 202 of the semiconductor device 200. The integrated circuit devices 208 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

A front end transistor structure may include a plurality of source/drain regions, which may correspond to doped regions of the substrate 206, separated by a channel region in the substrate 206. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 210 is included over the substrate 206. The dielectric layer 210 includes an interlayer dielectric (ILD) layer, an etch stop layer (ESL), and/or another type of dielectric layer. The dielectric layer 210 includes dielectric material(s) that enable various portions of the substrate 206 and/or the integrated circuit devices 208 to be selectively etched or protected from etching, and/or to electrically isolate the integrated circuit devices 208 in the device layer 202. The dielectric layer 210 includes a silicon nitride (SiₓN_{y}), an oxide (e.g., a silicon oxide (SiOₓ) and/or another oxide material), and/or another type of dielectric material. The dielectric layer 210 may extend in the x-direction and/or in the y-direction in the semiconductor device 200. Contacts 212 (e.g., source/drain contacts, gate contacts) may extend through the dielectric layer 210 and between the integrated circuit devices 208 and the interconnect layer 204. The contacts may electrically connect the integrated circuit devices 208 to the interconnect layer 204. The contacts 212 may include vias, plugs, and/or another type of elongated electrically conductive structures. The contacts 212 may include tungsten (W), cobalt (Co), ruthenium (Ru), titanium (Ti), aluminum (Al), and/or gold (Au), among other electrically conductive materials.

The interconnect layer 204 includes a plurality of dielectric layers (e.g., back end dielectric layers) that are arranged in a direction (e.g., the z-direction) that is approximately perpendicular to the top surface of the substrate 206. The dielectric layers may include ILD layers 214 and ESLs 216 that are arranged in an alternating manner in the z-direction. The ILD layers 214 and the ESLs 216 may extend in the x-direction and/or in the y-direction in the semiconductor device 200. The ILD layers 214 may be interleaved by a plurality of ESLs 216. A thickness of a bottommost one of the ILD layers 214 may be less than a thickness of at least one of the ILD layers 214 above the bottommost one of the ILD layers 214.

The ILD layers 214 may each include a low dielectric constant (low-k) oxide material such as silicon oxide (SiOₓ) or undoped silicate glass (USG). Additionally and/or alternatively, the ILD layers 214 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 214 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 216 may each include a silicon nitride (SiₓN_{y}), silicon carbide (SiC), silicon oxynitride (SiON), and/or another suitable dielectric material. In some implementations, an ILD layer 214 and an ESL 216 include different dielectric materials to provide etch selectivity to enable various structures to be formed in the interconnect layer 204. For example, the ILD layers 214 may each include a low-k dielectric material such as USG, and the ESLs 216 may each include a high-k dielectric material such as silicon nitride (SiₓN_{y}) or silicon carbide (SiC). Additionally and/or alternatively, two or more ESLs 216 may include different materials. For example, one or more first ESLs 216 may include silicon nitride (SiₓN_{y}), and one or more second ESLs 216 may include silicon carbide (SiC).

The interconnect layer 204 includes a plurality of conductive structures that are arranged in a plurality of layers. The conductive structures may be electrically coupled and/or physically coupled with one or more of the integrated circuit devices 208 in the device layer 202. The conductive structures provide electrical routing that enables signals and/or power to be provided to and/or from the integrated circuit devices 208.

The layers of conductive structures may include a plurality of layers 218a-218f that are vertically arranged and alternate with a plurality of layers 220a-220e in the z-direction (e.g., vertically alternate). The layers 218a-218f each include a layer of metallization structures 222, and the layers 220a-220e each include a layer of interconnect structures 224. The metallization structures 222 and interconnect structures 224 may be referred to herein as metal lines, which are disposed in the ILD layers 214 and/or ESLs 216.

The layers 218a-218e of metallization structures 222 may be referred to as M-layers. For example, a layer 218a of metallization structures 222 (referred to as a metal-0 (M0) layer) may be located at the bottom of the interconnect layer 204 and may be coupled to the device layer 202. In particular, the metallization structures 222 in the M0 layer may be coupled to the contacts 212 (e.g., a contact layer referred to as “CO” layer) of the integrated circuit devices 208 in the device layer 202. A layer 218b of metallization structures 222 (referred to as a metal-1 layer (M1) layer) may be located above the layer 218a of metallization structures 222 in the interconnect layer 204, a layer 218c of metallization structures 222 (referred to as a metal-2 layer (M2) layer) may be located above a layer 218b of metallization structures 222, and so on.

A layer 220a of interconnect structures 224 (referred to as a via-1 (V0) layer) may be included between the M0 layer and the M1 layer to interconnect the M0 layer and the M1 layer, a layer 220b of interconnect structures 224 (referred to as a via-2 (V1) layer) may be included between the M1 layer and the M2 layer to interconnect the M1 layer and the M2 layer, and so on.

As further shown in FIG. 2A, a semiconductor structure 226 including a first trench capacitor structure 228 and a second trench capacitor structure 230 is included in the interconnect layer 204 of the semiconductor device 200. The first trench capacitor structure 228 and/or second trench capacitor structure 230 may be an example structural implementation of the overflow capacitor 114 of the pixel sensor 100.

In general, a capacitor structure may include an MIM structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in a semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

Referring to FIG. 2A, the first trench capacitor structure 228 and the second trench capacitor structure 230 may each include a DTC structure that extends through and/or may be included in one or more dielectric layers in the interconnect layer 204, such as one or more ILD layers 214 and/or one or more ESLs 216. In some implementations, a first trench capacitor structure 228 and/or a second trench capacitor structure 230 are configured to store a charge (e.g., a photocurrent) for an integrated circuit device 208 (e.g., a pixel sensor) in the semiconductor device 200. In some implementations, one or more integrated circuit devices 208 are electrically coupled to a first trench capacitor structure 228 and/or a second trench capacitor structure 230 to form a memory cell (e.g., a dynamic random access memory (DRAM) cell or another type of capacitor-based memory cell) in the semiconductor device 200. In some implementations, a first trench capacitor structure 228 and/or a second trench capacitor structure 230 are configured to provide charge decoupling for one or more integrated circuit devices 208. In some implementations, a first trench capacitor structure 228 and/or a second trench capacitor structure 230 are configured to perform another function in the semiconductor device 200.

The first trench capacitor structure 228 may be electrically coupled and/or physically coupled to a first bottom contact 232a at a bottom of the first trench capacitor structure 228. The second trench capacitor structure 230 may be electrically coupled and/or physically coupled to a second bottom contact 232b at a bottom of the second trench capacitor structure 230. The first bottom contact 232a and the second bottom contact 232b may each include one or more conductive structures in the interconnect layer 204, such as one or more metallization structures 222 and/or one or more interconnect structures 224, among other examples. In some implementations, the first bottom contact 232a may electrically connect the first bottom electrode layer 234a to an integrated circuit device 208 (e.g., transistor of a pixel sensor). In some implementations, the second bottom contact 232b may electrically connect the second bottom electrode layer 234b to an integrated circuit device 208 (e.g., transistor of a pixel sensor).

The first trench capacitor structure 228 includes one or more trenches on the first bottom contact 232a and the second trench capacitor structure 230 includes one or more trenches on the second bottom contact 232b. The first and second bottom contacts 232a and 232b may be included in an ILD layer 214 and/or ESL 216 in the interconnect layer 204 of the semiconductor device 200. Trenches of the first trench capacitor structure 228 and the second trench capacitor structure 230 may extend through one or more dielectric layers in the interconnect layer 204 of the semiconductor device 200, including through one or more ILD layers 214 and/or one or more ESLs 216. In some implementations, the trenches may have a high aspect ratio, which is a ratio of a depth (or height) of the trenches to a lateral width (or critical dimension) of the trenches. Thus, the first trench capacitor structure 228 and the second trench capacitor structure 230 each may be referred to as a DTC structure. In some implementations, the aspect ratio of a trench may be approximately 10:1 or greater. In some implementations, a trench may have an aspect ratio that is included in the range of approximately 20:1 to approximately 50:1. However, other values and ranges are within the scope of the present disclosure.

As further shown in FIG. 2A, the first trench capacitor structure 228 and the second trench capacitor structure 230 each include a plurality of conformal layers that conform to the profile of the trenches. The conformal layers of the first trench capacitor structure 228 may include a first bottom electrode layer 234a, a first insulator layer 236a on the first bottom electrode layer 234a, and a first top electrode layer 238a on the first insulator layer 236a. The conformal layers of the second trench capacitor structure 230 may include a second bottom electrode layer 234b, a second insulator layer 236b on the second bottom electrode layer 234b, and a second top electrode layer 238b on the second insulator layer 236b. The first bottom electrode layer 234a, the first insulator layer 236a, and the first top electrode layer 238a may each conform to the profiles of the trenches such that the first bottom electrode layer 234a, the first insulator layer 236a, and the first top electrode layer 238a conform to the sidewalls and the bottom surfaces of the trenches. The second bottom electrode layer 234b, the second insulator layer 236b, and the second top electrode layer 238b may each conform to the profiles of the trenches such that the second bottom electrode layer 234b, the second insulator layer 236b, and the second top electrode layer 238b conform to the sidewalls and the bottom surfaces of the trenches.

The first trench capacitor structure 228 further includes a first dielectric fill layer 240a on the first top electrode layer 238a. The second trench capacitor structure 230 further includes a second dielectric fill layer 240b on the second top electrode layer 238b. In some implementations, the first dielectric fill layer 240a and the second dielectric fill layer 240b fill in the remaining areas of the trenches of the first trench capacitor structure 228 and of the second trench capacitor structure 230. Alternatively, the first dielectric fil layer 240a and the second dielectric fill layer 240b may be omitted. In this case, the first top electrode layer 238a and the second top electrode layer 238b may be fill layers that fill in the remaining areas of the trenches of the first trench capacitor structure 228 and of the second trench capacitor structure 230.

In some implementations, an adhesion layer (not shown) may be included in the trenches under the first and second bottom electrode layers 234a and 234b to promote adhesion of the first and second bottom electrode layers 234a and 234b to the dielectric layers (e.g., the one or more ILD layers 214 and/or ESLs 216) in which the trenches are formed and/or to the first and second bottom contacts 232a and 232b. An adhesion layer may also act as a barrier layer that prevents upward migration of an electrically conductive material (e.g., copper (Cu)) of the first and second bottom contacts 232a and 232b into the first and second bottom electrode layers 234a and 234b. An adhesion layer may include tantalum (Ta), tantalum nitride (TaN), and/or another suitable adhesion material.

The first bottom electrode layer 234a, the first insulator layer 236a, and the first top electrode layer 238a correspond to an MIM structure of the first trench capacitor structure 228. The second bottom electrode layer 234b, the second insulator layer 236b, and the second top electrode layer 238b correspond to an MIM structure of the second trench capacitor structure 230. Thus, the first trench capacitor structure 228 and the second trench capacitor structure 230 may also be referred to as MIM capacitor structures. The first and second bottom electrode layers 234a and 234b (also referred to as capacitor bottom metals (CBMs)) and the first and second top electrode layers 238a and 238b (also referred to as capacitor top metals (CTMs)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the first and second bottom electrode layers 234a and 234b and the first and second top electrode layers 238a and 238b include the same material or the same material composition. In some implementations, the first and second bottom electrode layers 234a and 234b and the first and second top electrode layers 238a and 238b include different materials or different material compositions.

The first insulator layer 236a and the second insulator layer 236b may each include one or more electrically insulating materials. In some implementations, the first insulator layer 236a and the second insulator layer 236b each include one or more low-k dielectric materials such as silicon oxide (SiOₓ such as SiO₂). Additionally and/or alternatively, the first insulator layer 236a and the second insulator layer 236b may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the first insulator layer 236a and the second insulator layer 236b are multiple-layer stacks that include a plurality of dielectric layers. For example, the first insulator layer 236a and the second insulator layer 236b may include a ZrO₂/Al₂O₃/ZrO₂ (ZAZ) layer stack.

In some implementations, the first trench capacitor structure 228 includes a plurality of trenches, and the MIM structure of the first trench capacitor structure 228 (e.g., the first bottom electrode layer 234a, the first insulator layer 236a, and the first top electrode layer 238a) may extend along the sidewalls and bottom surfaces of the plurality of trenches, and between the plurality of trenches. The trenches may be laterally arranged and spaced apart by a distance in the x-direction. In this way, including a plurality of trenches in the first trench capacitor structure 228 enables the length (and therefore the area) of the MIM structure of the first trench capacitor structure 228 (e.g., of the first bottom electrode layer 234a, the first insulator layer 236a, and the first top electrode layer 238a) to be extended, thereby increasing the capacitance of the first trench capacitor structure 228. Similarly, in some implementations, the second trench capacitor structure 230 includes a plurality of trenches, and the MIM structure of the second trench capacitor structure 230 (e.g., the second bottom electrode layer 234b, the second insulator layer 236b, and the second top electrode layer 238b) may extend along the sidewalls and bottom surfaces of the plurality of trenches, and between the plurality of trenches. The trenches may be laterally arranged and spaced apart by a distance in the x-direction. In this way, including a plurality of trenches in the second trench capacitor structure 230 enables the length (and therefore the area) of the MIM structure of the second trench capacitor structure 230 (e.g., of the second bottom electrode layer 234b, the second insulator layer 236b, and the second top electrode layer 238b) to be extended, thereby increasing the capacitance of the second trench capacitor structure 230.

As further shown in FIG. 2A, the first bottom electrode layer 234a, the first insulator layer 236a, and the first top electrode layer 238a may extend over a first portion of the ILD layer 214 in which the trenches are formed that is between the first trench capacitor structure 228 and the second trench capacitor structure 230. Similarly, the second bottom electrode layer 234b, the second insulator layer 236b, and the second top electrode layer 238b may extend over a second portion of the ILD layer 214 in which the trenches are formed that is between the first trench capacitor structure 228 and the second trench capacitor structure 230.

The first bottom electrode layer 234a extends a distance in the x-direction over the first portion of the ILD layer 214 and toward the second capacitor structure 230, and the first insulator layer 236a and the first top electrode layer 238a extend a farther distance in the x-direction over the first portion of the ILD layer 214 and toward the second capacitor structure 230 such that edges of the first insulator layer 236a and the first top electrode layer 238a are closer to the second capacitor structure 230 than an edge of the first bottom electrode layer 234a. Similarly, the second bottom electrode layer 234b extends a distance in the x-direction over the second portion of the ILD layer 214 toward the first capacitor structure 228, and the second insulator layer 236b and the second top electrode layer 238b extend a farther distance in the x-direction over the second portion of the ILD layer 214 toward the first capacitor structure 228 such that edges of the second insulator layer 236b and the second top electrode layer 238b are closer to the first capacitor structure 228 than an edge of the second bottom electrode layer 234b. For example, the farther distance in the x-direction extended by the first insulator layer 236a and the first top electrode layer 238a, and by the second insulator layer 236b and the second top electrode layer 238b is designated as dimension D1. In some implementations, the dimension D1 is included in the range of approximately 200 nanometers to approximately 500 nanometers. If the dimension D1 is greater than approximately 500 nanometers, an area occupied by the first and second trench capacitor structures 228 and 230 may be too large and prevent semiconductor device size from scaling down. If the dimension D1 is smaller than approximately 200 nanometers, there may be current leakage between the first bottom electrode layer 234a and the first top electrode layer 238a, and/or between the second bottom electrode layer 234b and the second top electrode layer 238b. However, other values for the range of the dimension D1 are within the scope of this disclosure.

As a result of the farther extension of the first insulator layer 236a and the first top electrode layer 238a than the first bottom electrode layer 234a, and as a result of the farther extension of the second insulator layer 236b and the second top electrode layer 238b than the second bottom electrode layer 234b, stepped structures S1 and S2 are formed. The stepped structure S1 includes a portion of the first insulator layer 236a extending around an edge of the first bottom electrode layer 234a and onto the first portion of the ILD layer 214 between the first and second capacitor structures 228 and 230. The stepped structure S1 further includes a portion of the first top electrode layer 238a conformally formed on the portion of the first insulator layer 236a. Similarly, the stepped structure S2 includes a portion of the second insulator layer 236b extending around an edge of the second bottom electrode layer 234b and onto the second portion of the ILD layer 214 between the first and second capacitor structures 228 and 230. The stepped structure S2 further includes a portion of the second top electrode layer 238b conformally formed on the portion of the second insulator layer 236b. In some implementations, a depth (or height) D2 in the z-direction of the stepped structures S1 and S2 is included in the range of approximately 200 angstroms to approximately 500 angstroms. However, other values for the range of the dimension D2 are within the scope of this disclosure.

The interconnect layer 204 further includes a top metallization structure 242, a first contact structure 244, and a second contact structure 246. The first contact structure 244 is disposed in the ILD layer 214 and under the top metallization structure 242. The first contact structure 244 may be an interconnect structure (e.g., via) in physical contact with the top metallization structure 242. A first portion of the first contact structure 244 may be disposed over and land on a top surface of the first top electrode layer 238a, such that the first portion of the first contact structure 244 is in physical contact with the top surface of the first top electrode layer 238a. A second portion of the first contact structure 244 may be disposed over and land on a top surface of the second top electrode layer 238b, such that the second portion of the first contact structure 244 is in physical contact with the top surface of the second top electrode layer 238b.

The second contact structure 246 is disposed under the first contact structure 244. The second contact structure 246 is disposed in the ILD layer 214 between the first and second capacitor structures 228 and 230, and may be an interconnect structure (e.g., via) in physical contact with the first contact structure 244. In some implementations, the first and second contact structures 244 and 246 may form an integrated structure where the first and second contact structures 244 and 246 are two parts of an integral contact structure and the second contact structure 246 extends from the first contact structure 244. The second contact structure 246 is disposed in a space between edges of the first top electrode layer 238a and the first insulator layer 236a, and edges of the second top electrode layer 238b and the second insulator layer 236b. Side portions of the second contact structure 246 may be in physical contact with the edges of the first top electrode layer 238a and the first insulator layer 236a, and the edges of the second top electrode layer 238b and the second insulator layer 236b. The second contact structure 246 extends through the ILD layer 214 between the first and second capacitor structures 228 and 230 to land on a metallization structure 248. The metallization structure 248 may be connected to one or more underlying metallization (M) levels and via (V) levels in the interconnect layer 204.

An x-direction dimension D4 (e.g., width) of the second contact structure 246 is smaller than an x-direction dimension D3 (e.g., width) of the first contact structure 244. In some implementations, the x-direction dimension D4 (e.g., width) of the second contact structure 246 is equal to or approximately equal to a width of the space between edges of the first top electrode layer 238a and the first insulator layer 236a of the first trench capacitor structure 228, and edges of the second top electrode layer 238b and the second insulator layer 236b of the second trench capacitor structure 230.

The metallization structures 222, 242, and 248, and the first and second bottom contacts 232a and 232b may include a combination of trenches, metallization layers, conductive traces, and/or other types of conductive structures. The interconnect structures 224, first contact structure 244, and second contact structure 246 may include a combination of vias, interconnects, and/or other types of conductive structures. The metallization structures 222, 242, and 248, the first and second bottom contacts 232a and 232b, the interconnect structures 224, the first contact structure 244, and the second contact structure 246 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 204 and the metallization structures 222, 242, and 248, and the first and second bottom contacts 232a and 232b, and/or between the dielectric layers of the interconnect layer 204 and the interconnect structures 224, the first contact structure 244, and the second contact structure 246. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., the top metallization structure 242) may be coupled to connection structures at the top of the semiconductor device 200. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., top metallization structure 242) may be coupled to bonding structures, such as bonding pads and/or bonding vias.

FIG. 2B is a diagram of an example semiconductor device 250 described herein. The example semiconductor device 250 is similar to the example semiconductor device 200, except that each of the trenches of the first trench capacitor structure 228 and of the second trench capacitor structure 230 in the example semiconductor device 250 have a V-shape instead of a U-shape as in the example semiconductor device 200. In the example semiconductor device 250, the first bottom electrode layer 234a, the first insulator layer 236a, and the first top electrode layer 238a may each conform to the profiles of the V-shaped trenches such that the first bottom electrode layer 234a, the first insulator layer 236a, and the first top electrode layer 238a conform to the sidewalls and the bottom surfaces of the V-shaped trenches. The second bottom electrode layer 234b, the second insulator layer 236b, and the second top electrode layer 238b may each conform to the profiles of the V-shaped trenches such that the second bottom electrode layer 234b, the second insulator layer 236b, and the second top electrode layer 238b conform to the sidewalls and the bottom surfaces of the V-shaped trenches.

As indicated above, FIGS. 2A and 2B are provided as an example. Other examples may differ from what is described with regard to FIGS. 2A and 2B.

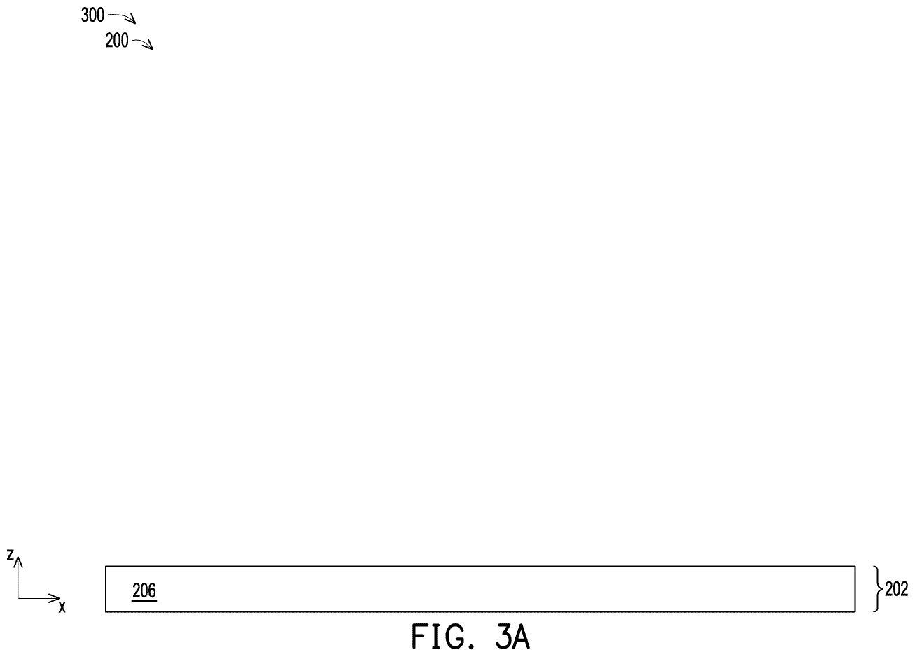

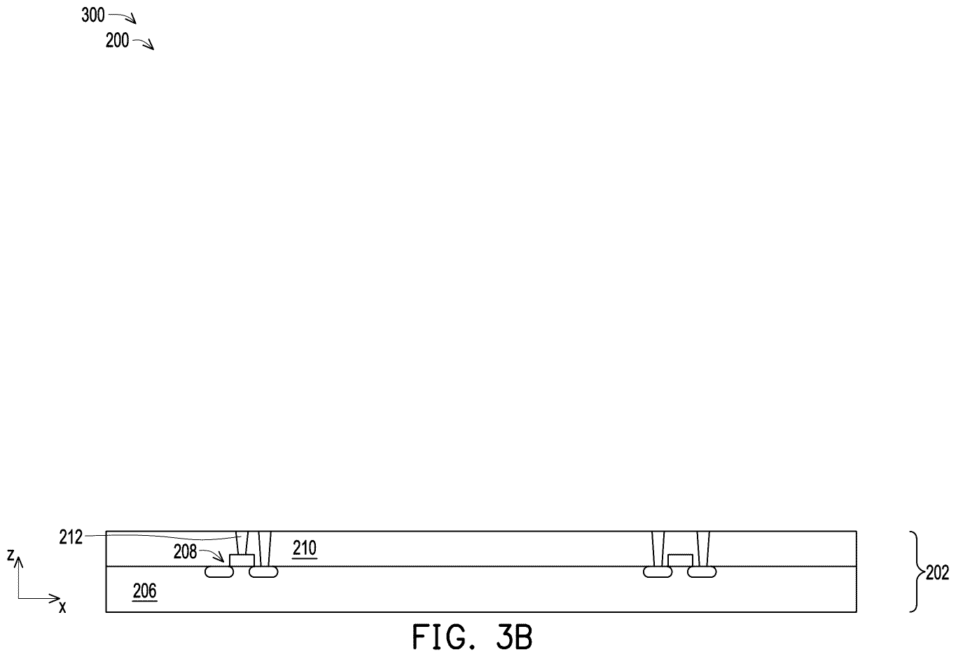

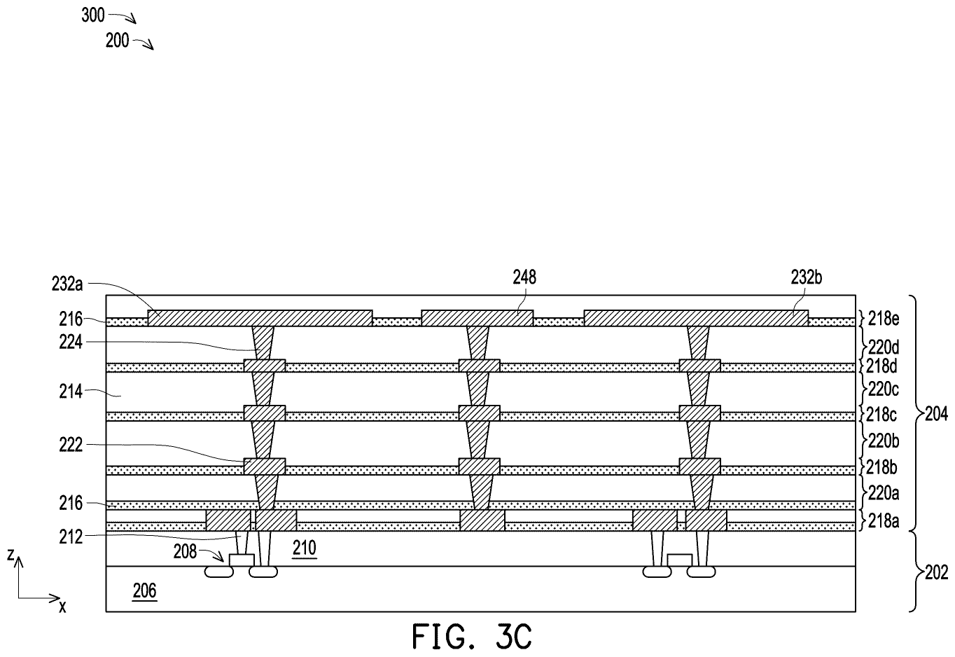

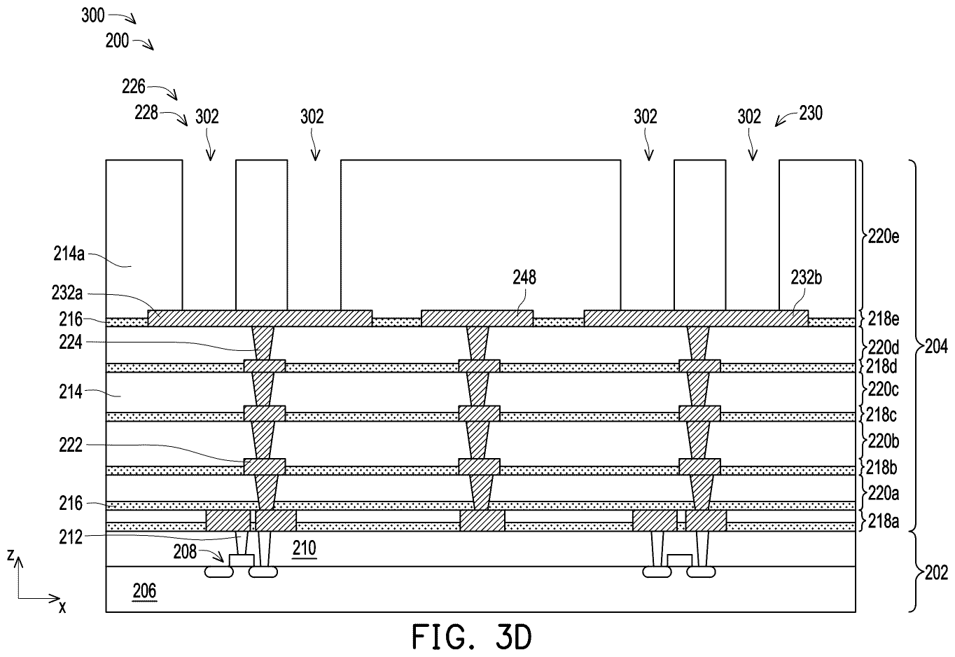

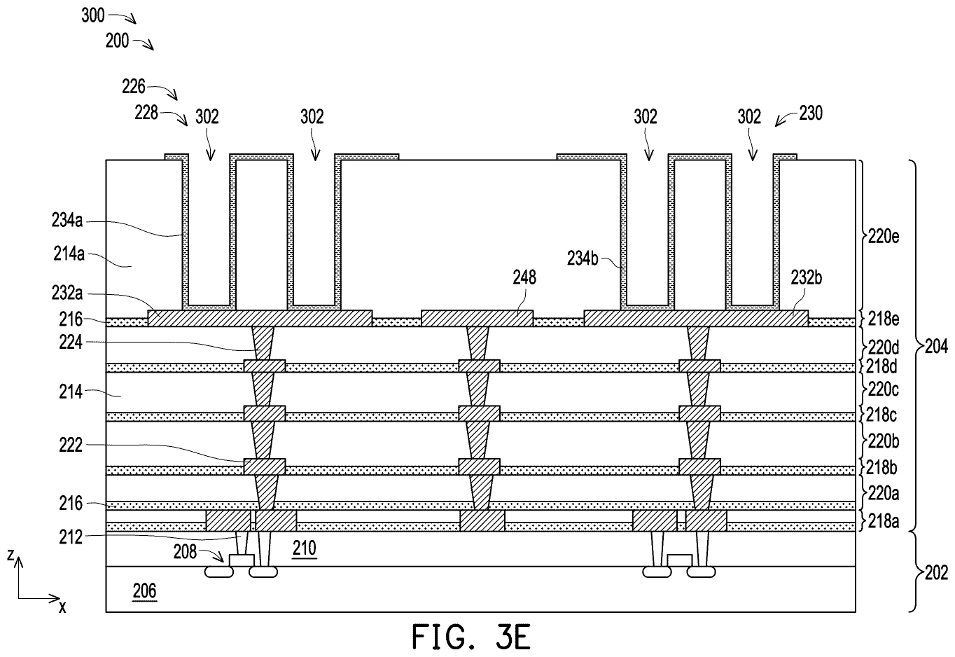

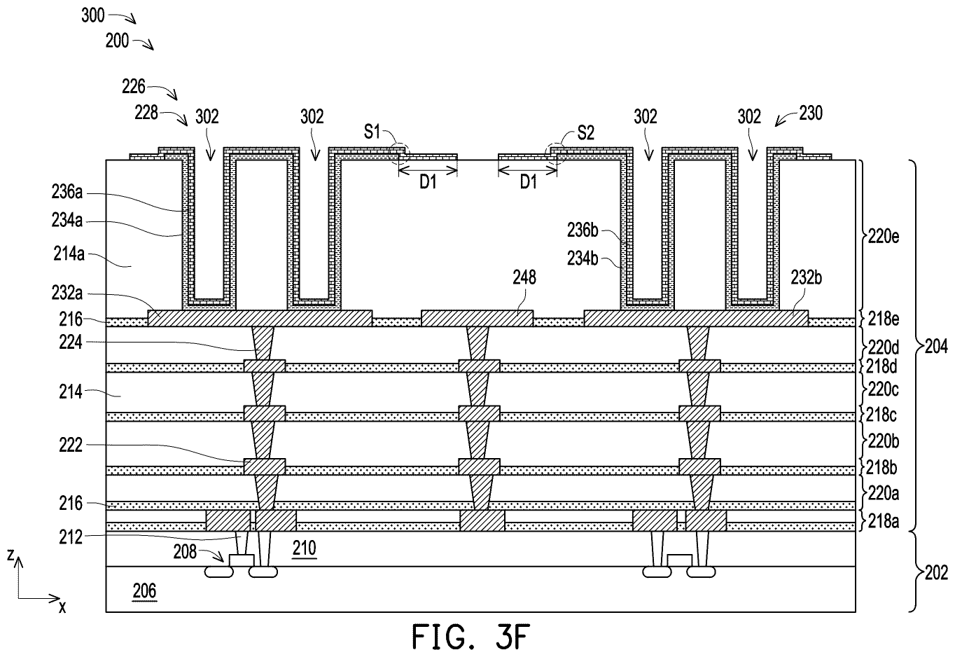

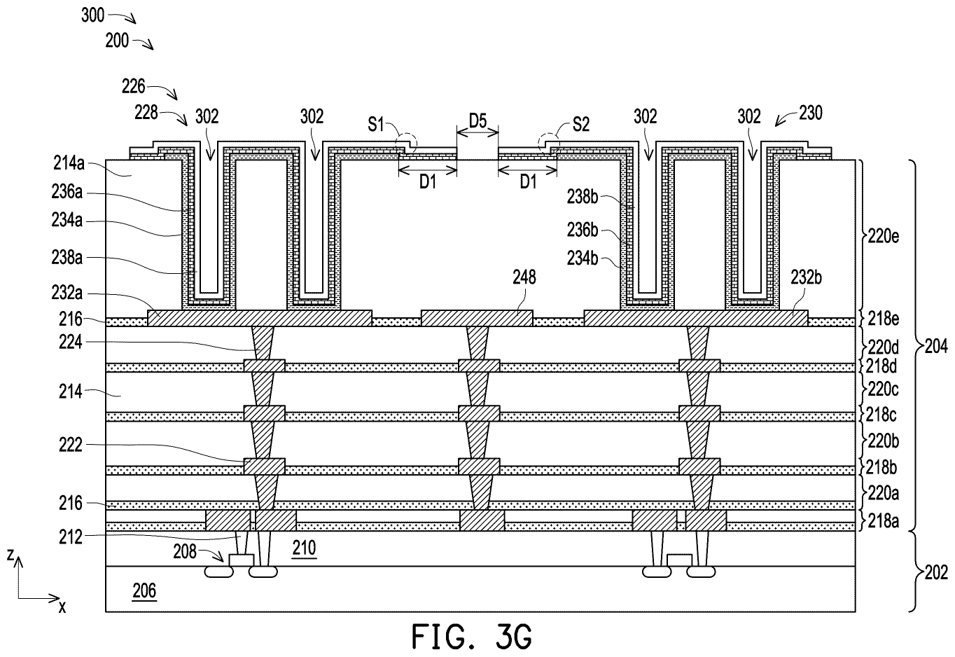

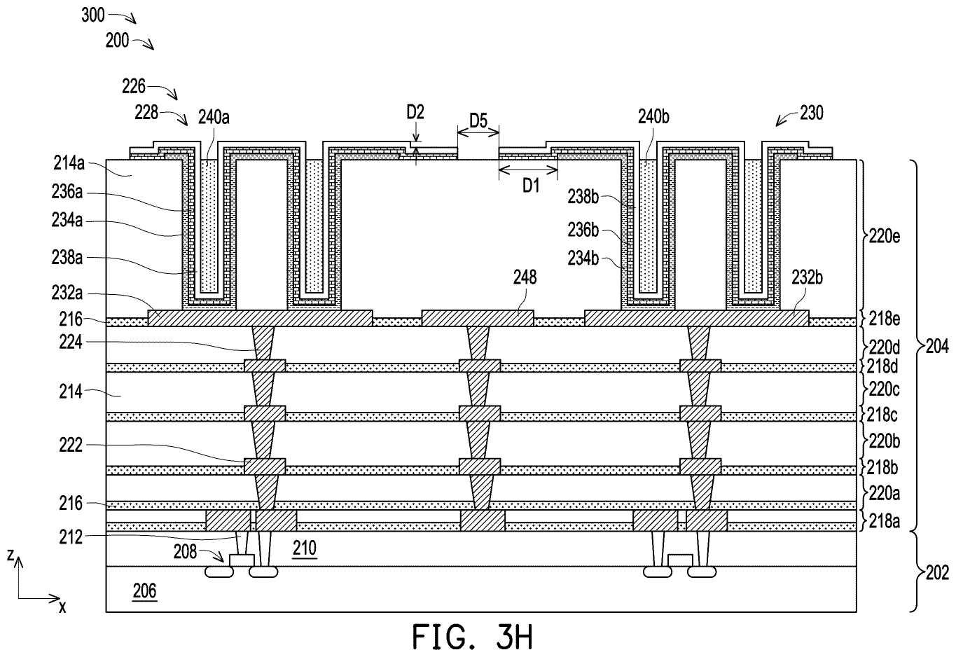

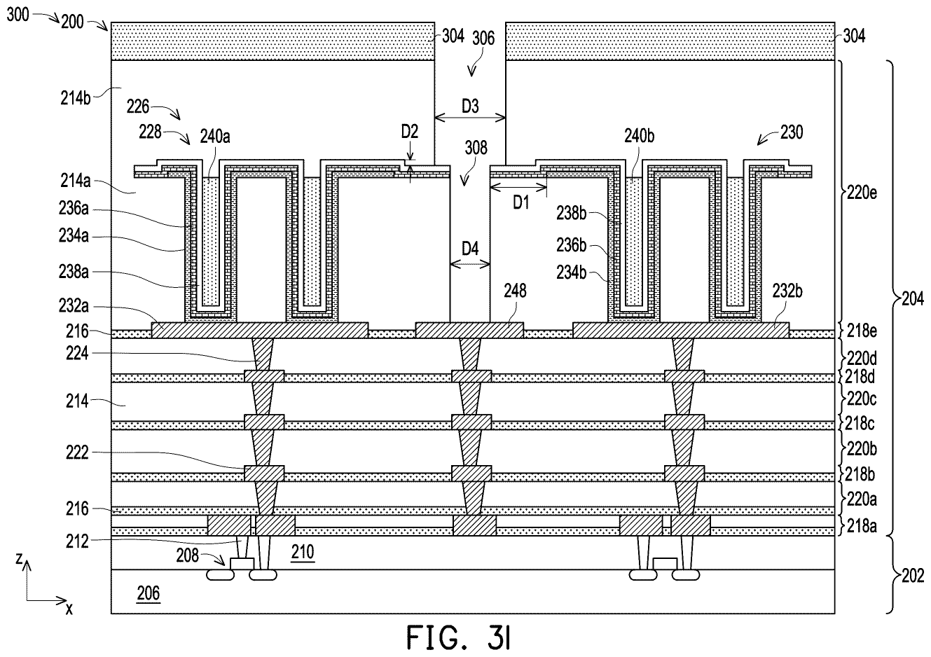

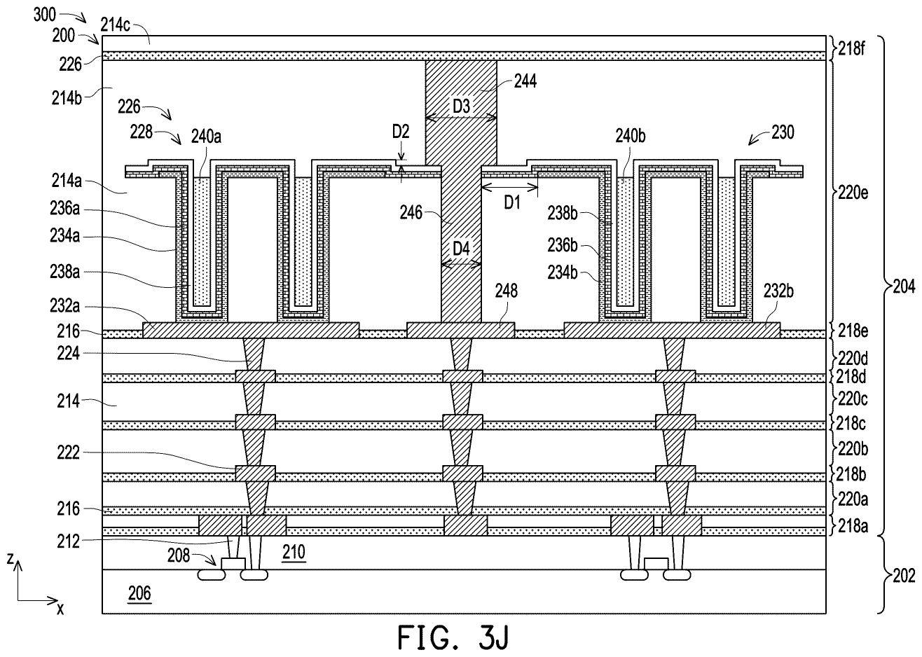

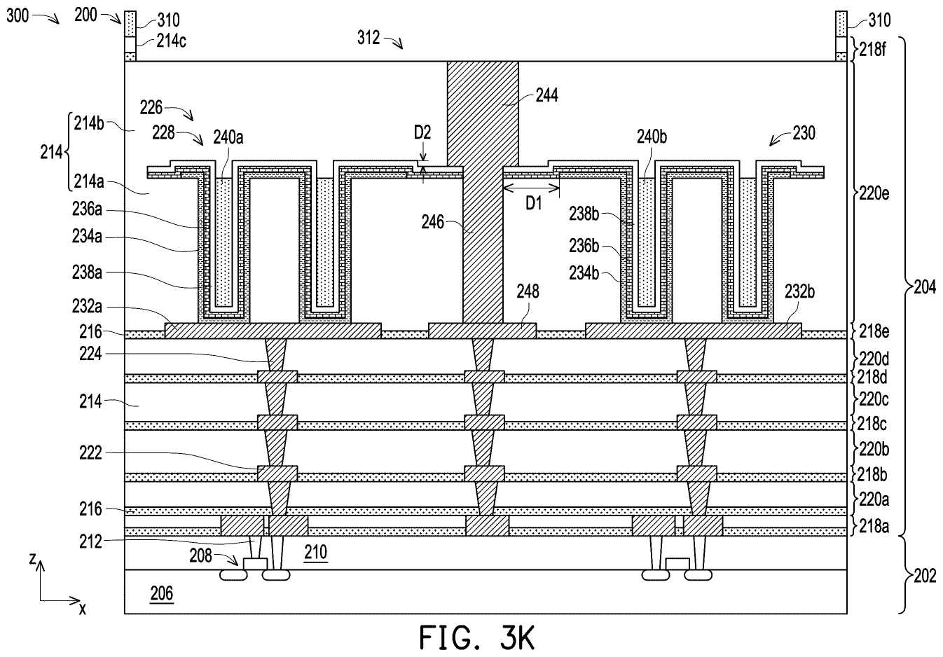

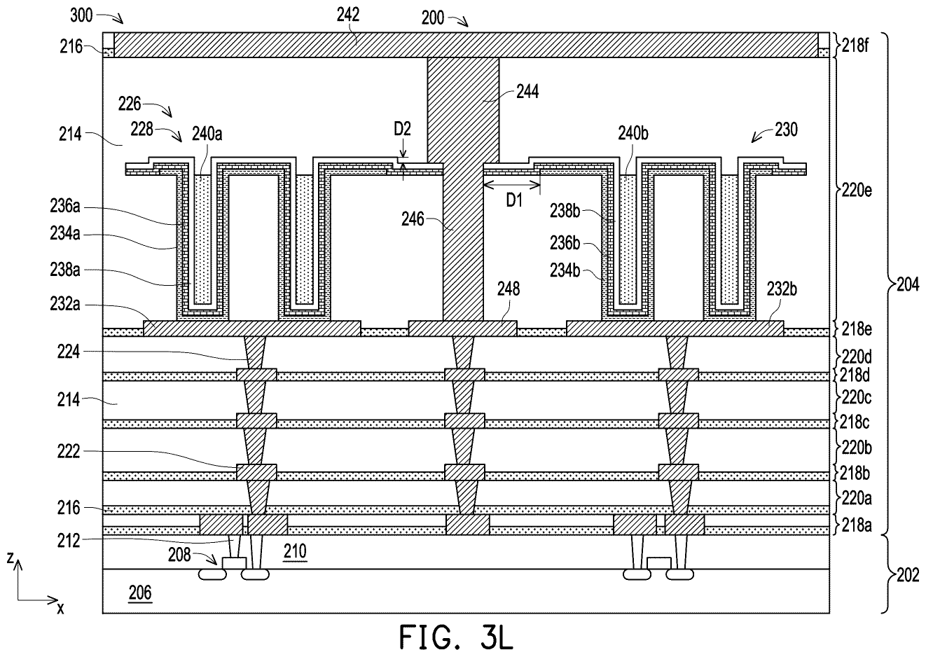

FIGS. 3A-3L are diagrams of an example implementation 300 of forming the semiconductor device 200 described herein. In some implementations, one or more of the semiconductor processing operations described in connection with FIGS. 3A-3L may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate 206 is provided. The substrate 206 may be provided in the form of a semiconductor wafer such as a silicon (Si) wafer, an SOI wafer, and/or another type of semiconductor work piece. The semiconductor device 200 may be formed on the semiconductor wafer with other semiconductor devices.

As shown in FIG. 3B, the integrated circuit devices 208 may be formed in and/or on the substrate 206 in the device layer 202 of the semiconductor device 200. One or more semiconductor processing tools may be used to form one or more portions of the integrated circuit devices 208. For example, an ion implantation tool may be used to dope one or more regions in the substrate 206 with one or more types of dopants to form well regions, implant regions, and/or other types of doped regions in the substrate 206 for the integrated circuit devices 208. As another example, a deposition tool may be used to perform various deposition operations to deposit layers and/or structures of the integrated circuit devices 208, and/or to deposit photoresist layers for etching the substrate 206 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 206 and/or portions of the deposited layers to form the integrated circuit devices 208. As another example, a planarization tool may be used to planarize portions of the integrated circuit devices 208. As another example, a plating tool may be used to deposit metal structures and/or layers of the integrated circuit devices 208.

As further shown in FIG. 3B, a deposition tool is used to deposit the dielectric layer 210 over and/or on the substrate 206 and over and/or on the integrated circuit devices 208. A deposition tool may be used to deposit the dielectric layer 210 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 210 after the dielectric layer 210 is deposited.

As further shown in FIG. 3B, the contacts 212 of the integrated circuit devices 208 may be formed through the dielectric layer 210. The contacts 212 may be formed in recesses in the dielectric layer 210. In some implementations, a pattern in a photoresist layer is used to etch the dielectric layer 210 to form the recesses. In these implementations, a deposition tool may be used to form the photoresist layer on the dielectric layer 210. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 210 based on a pattern to form the recesses.

The contacts 212 may be formed in the recesses. In some implementations, a contact 212 (e.g., a gate contact) is formed on a gate structure of an integrated circuit device 208. In some implementations, a contact 212 (e.g., a source/drain contact) is formed on a source/drain region of an integrated circuit device 208. A deposition tool may be used to deposit the material of the contacts 212 in the recesses using a CVD technique, a PVD technique, an ALD technique, an electroplating technique, and/or another suitable deposition technique. The material of the contacts 212 may be deposited in one or more deposition operations. In some implementations, a seed layer is first deposited, and the material of the contacts 212 is deposited on the seed layer. In some implementations, a planarization tool is used to perform a planarization operation (e.g., a CMP operation) to planarize the contacts 212 after the contacts 212 are deposited such that the tops of the contacts 212 are approximately co-planar with the top of the dielectric layer 210.

As shown in FIG. 3C, a first portion of the interconnect layer 204 of the semiconductor device 200 is formed above the dielectric layer 210. One or more deposition tools are used to deposit alternating layers of ILD layers 214 and ESLs 216 in the first portion of the interconnect layer 204 of the semiconductor device 200. In this way, the ILD layers 214 and ESLs 216 may be arranged in the z-direction in the semiconductor device 200. One or more deposition tools may be used to deposit each of the ILD layers 214 and each of the ESLs 216 using a PVD technique, an ALD technique, a CVD technique, an oxidation technique, and/or another suitable deposition technique. In some implementations, a planarization tool may be used to planarize the ILD layers 214 and/or the ESLs 216 after the ILD layers 214 and/or the ESLs 216 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 222 and 248, to form the interconnect structures 224, and to form the first and second bottom contacts 232a and 232b in the first portion of the interconnect layer 204 of the semiconductor device 200.

In some implementations, the first portion of the interconnect layer 204 may be formed in a plurality of layers. For example, an ILD layer 214 and an ESL 216 may be formed (e.g., using one or more deposition tools and/or one or more planarization tools), recesses may be formed in and/or through the ILD layer 214 and the ESL 216 (e.g., using an exposure tool, a developer tool, and/or an etch tool), and the layer 218a (e.g., the M0 layer) of metallization structures 222 may be formed in the ILD layer 214 and the ESL 216 (e.g., using one or more deposition tools and/or one or more planarization tools). Another ILD layer 214 and another ESL 216 may be formed, and the layer 220a (e.g., the V0 layer) of interconnect structures 224 may be formed in the ILD layer 214 and the ESL 216. The layers 218b-218f, 220b-220e may be formed in a similar manner.

One or more deposition tools may be used to deposit the metallization structures 222 and 248, the interconnect structures 224, and/or the first and second bottom contacts 232a and 232b using a PVD technique, an ALD technique, a CVD technique, an electroplating technique (e.g., an electro-chemical plating technique), and/or another suitable deposition technique. In some implementations, a planarization tool may be used to planarize the metallization structures 222 and 248, the interconnect structures 224, and/or the first and second bottom contacts 232a and 232b after the metallization structures 222 and 248, the interconnect structures 224, and/or the first and second bottom contacts 232a and 232b are deposited.

As shown in FIG. 3D, a first trench capacitor structure 228 and a second trench capacitor structure 230 may be formed in an ILD layer 214a in the interconnect layer 204. The first trench capacitor structure 228 and the second trench capacitor structure 230 may be formed such that the trenches 302 of the first trench capacitor structure 228 land on the first bottom contact 232a in the interconnect layer 204, and the trenches 302 of the second trench capacitor structure 230 land on the second bottom contact 232b in the interconnect layer 204.

An etch operation is performed to etch through the ILD layer 214a to form the trenches 302 of the first trench capacitor structure 228 and the second trench capacitor structure 230. The etch operation may include a gas-based etch operation in which a gas-based etchant is used. An etch tool may be used to perform the gas-based etch operation.

The gas-based etchant that is used to etch the ILD layer 214a may include a fluorine-based gas etchant. The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the trenches 302 of the first trench capacitor structure 228 and the second trench capacitor structure 230. For example, a first etch operation (referred to as a “main etch” operation) may be performed to form the trenches 302 to an ESL (not shown) disposed over the first and second bottom contacts 232a and 232b. In other words, etching in the first etch operation stops at an ESL such that an ESL remains between the bottom of the trenches 302 and the underlying first bottom contact 232a and second bottom contact 232b. The ESL may be kept over the first bottom contact 232a and second bottom contact 232b to prevent the first bottom contact 232a and second bottom contact 232b from being exposed to oxygen and other contaminants that might otherwise result in oxidation of the first bottom contact 232a and second bottom contact 232b. After the first etch operation, the trenches 302 may have tapered sidewalls, resulting in the lateral width of the trenches 302 decreasing from the tops of the trenches 302 to the bottoms of the trenches.

A second etch operation (referred to as an “over etch” operation) may be performed after the first etch operation to shape the bottom portions of the trenches 302. In particular, the second etch operation may be performed to increase the verticality of the sidewalls of the trenches 302, thereby lessening the taper in the sidewalls of the trenches 302. A third etch operation (referred to as a “linear removal” etch operation) may be performed to etch through the ESL at the bottom of the trenches 302 to extend the trenches 302 through the ESL and to the underlying first bottom contact 232a and second bottom contact 232b. Thus, the first bottom contact 232a and second bottom contact 232b are exposed through the trenches 302 after the third etch operation. The third etch operation may be performed using a fluorine-based etchant such as a carbon fluoride-based (CFₓ such as CF₄) gas etchant.

As shown in FIG. 3E, the first bottom electrode layer 234a and the second bottom electrode layer 234b may be deposited on the sidewalls and on the bottom surfaces of the trenches 302. The bottom surfaces of the trenches 302 correspond to the top surfaces of the first bottom contact 232a and of the second bottom contact 232b, and thus the first bottom electrode layer 234a and the second bottom electrode layer 234b may be in physical contact with the top surfaces of the first bottom contact 232a and of the second bottom contact 232b. The first bottom electrode layer 234a and the second bottom electrode layer 234b may also be deposited on the top surface of the ILD layer 214a adjacent to the trenches 302 of each of the first and second trench capacitor structures 228 and 230, and on the top surface of the ILD layer 214a between adjacent first and second trench capacitor structures 228 and 230, such that the first bottom electrode layer 234a and the second bottom electrode layer 234b may be in physical contact with the top surface of the ILD layer 214a. In some implementations, a deposition tool is used to conformally deposit the first bottom electrode layer 234a and the second bottom electrode layer 234b such that the first bottom electrode layer 234a and the second bottom electrode layer 234b conform to the profiles of the trenches 302. In some implementations, a conformal CVD technique and/or an ALD technique is used to deposit the first bottom electrode layer 234a and the second bottom electrode layer 234b.

As shown in FIG. 3F, the first insulator layer 236a and the second insulator layer 236b may be deposited on the first bottom electrode layer 234a and the second bottom electrode layer 234b, respectively. Thus, the first insulator layer 236a and the second insulator layer 236b are deposited on the sidewalls and on the bottom surfaces (which correspond to the top surfaces of the first bottom contact 232a and the second bottom contact 232b) of the trenches 302. The first insulator layer 236a and the second insulator layer 236b may also be deposited on the top surfaces of the first bottom electrode layer 234a and the second bottom electrode layer 234b, respectively, adjacent to the trenches 302 of each of the first and second trench capacitor structures 228 and 230. The first insulator layer 236a and the second insulator layer 236b may also be deposited on the top surfaces of the first bottom electrode layer 234a and the second bottom electrode layer 234b, respectively, where the first bottom electrode layer 234a and the second bottom electrode layer 234b are on the top surface of the ILD layer 214a between adjacent first and second trench capacitor structures 228 and 230. The first insulator layer 236a and the second insulator layer 236b are further deposited around edges of the first bottom electrode layer 234a and the second bottom electrode layer 234b, respectively, to be in physical contact with the top surface of the ILD layer 214a between adjacent first and second trench capacitor structures 228 and 230. The dimension D1 indicates the distance between an edge of the first bottom electrode layer 234a and an edge of the first insulator layer 236a and between an edge of the second bottom electrode layer 234b and an edge of the second insulator layer 236b on the top surface of the ILD layer 214a between adjacent first and second trench capacitor structures 228 and 230. The dimension D1 represents an additional distance in comparison to an extension distance of the first bottom electrode layer 234a that the first insulator layer 236a extends toward the second trench capacitor structure 230, and an additional distance in comparison to an extension distance of the second bottom electrode layer 234b that the second insulator layer 236b extends toward the first trench capacitor structure 228. The stepped structure S1 includes a portion of the first insulator layer 236a extending around the edge of the first bottom electrode layer 234a and onto the ILD layer 214 between the first and second capacitor structures 228 and 230. The stepped structure S2 includes a portion of the second insulator layer 236b extending around the edge of the second bottom electrode layer 234b and onto the ILD layer 214 between the first and second capacitor structures 228 and 230.

In some implementations, a deposition tool is used to conformally deposit the first insulator layer 236a and the second insulator layer 236b such that the first insulator layer 236a and the second insulator layer 236b conform to the profiles of the trenches 302. In some implementations, a conformal CVD technique and/or an ALD technique is used to deposit the first insulator layer 236a and the second insulator layer 236b.

As shown in FIG. 3G, the first top electrode layer 238a and the second top electrode layer 238b may be deposited on the first insulator layer 236a and the second insulator layer 236b, respectively. Thus, the first top electrode layer 238a and the second top electrode layer 238b are deposited on the sidewalls and on the bottom surfaces (which correspond to the top surfaces of the first bottom contact 232a and the second bottom contact 232b) of the trenches 302. The first top electrode layer 238a and the second top electrode layer 238b may also be deposited on the top surfaces of the first insulator layer 236a and the second insulator layer 236b, respectively, adjacent to the trenches 302 of each of the first and second trench capacitor structures 228 and 230. The first top electrode layer 238a and the second top electrode layer 238b may also be deposited on the top surfaces of the first insulator layer 236a and the second insulator layer 236b, respectively, where the first insulator layer 236a and the second insulator layer 236b are on the top surface of the ILD layer 214a between adjacent first and second trench capacitor structures 228 and 230. The first top electrode layer 238a and the second top electrode layer 238b are further deposited around edges of the first insulator layer 236a and the second insulator layer 236b, respectively, to be in physical contact with the top surface of the ILD layer 214a between adjacent first and second trench capacitor structures 228 and 230. The dimension D1 indicates the distance between an edge of the first bottom electrode layer 234a and an edge of the first top electrode layer 238a and between an edge of the second bottom electrode layer 234b and an edge of the second top electrode layer 238b on the top surface of the ILD layer 214a between adjacent first and second trench capacitor structures 228 and 230. The dimension D1 represents an additional distance in comparison to an extension distance of the first bottom electrode layer 234a that the first top electrode layer 238a extends toward the second trench capacitor structure 230, and an additional distance in comparison to an extension distance of the second bottom electrode layer 234b that the second top electrode layer 238b extends toward the first trench capacitor structure 228. The stepped structure S1 includes a portion of the first top electrode layer 238a extending around the edge of the first insulator layer 236a and conformally formed on a portion of the first insulator layer 236a between the first and second capacitor structures 228 and 230. The stepped structure S2 includes a portion of the second top electrode layer 238b extending around an edge of the second insulator layer 236b and conformally formed on a portion of the second insulator layer 236a between the first and second capacitor structures 228 and 230.

In some implementations, a deposition tool is used to conformally deposit the first top electrode layer 238a and the second top electrode layer 238b such that the first top electrode layer 238a and the second top electrode layer 238b conform to the profiles of the trenches 302. In some implementations, a conformal CVD technique and/or an ALD technique is used to deposit the first top electrode layer 238a and the second top electrode layer 238b.

As further shown in FIG. 3G, the stacked arrangement of the first bottom electrode layer 234a, the first insulator layer 236a, and the first top electrode layer 238a is spaced apart from the stacked arrangement of the second bottom electrode layer 234b, the second insulator layer 236b, and the second top electrode layer 238b by a distance D5 in the x-direction. The distance D5 represents the width of a space between edges of the first insulator layer 236a and first top electrode layer 238a and edges of the second insulator layer 236b and second top electrode layer 238b.

As shown in FIG. 3H, the remaining areas in the trenches 302 for the first capacitor structure 228 may be filled in by depositing a first dielectric fill layer 240a on the first top electrode layer 238a in the trenches 302. The remaining areas in the trenches 302 for the second capacitor structure 230 may be filled in by depositing a second dielectric fill layer 240b on the second top electrode layer 238b in the trenches 302. A deposition tool may be used to deposit the first and second dielectric fill layers 240a and 240b using a PVD technique, an ALD technique, a CVD technique, an oxidation technique, and/or another suitable deposition technique. The first and second dielectric fill layers 240a and 240b may be deposited as a singular layer that is then planarized using a planarization tool to remove excess material of the layer to define the first and second dielectric fill layers 240a and 240b.

As shown in FIG. 3I, an additional ILD layer 214b is deposited over the first and second trench capacitor structures 228 and 230 and over the ILD layer 214a. Following deposition of the additional ILD layer 214b, a dielectric masking layer 304 may be formed on the additional ILD layer 214b. The dielectric masking layer 304 may include a silicon oxynitride material (SiON) and/or another suitable dielectric material.

A deposition tool may be used to deposit the dielectric masking layer 304 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 304 after the dielectric masking layer 304 is deposited.

A photoresist layer may be formed above the dielectric masking layer 304, and a pattern may be formed in the photoresist layer. A deposition tool may be used to form the photoresist layer on the dielectric masking layer 304 (e.g., using a spin-coating technique or another suitable deposition technique). In some implementations, a bottom antireflective coating (BARC) is first deposited on the dielectric masking layer 304, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 304 based on the pattern in the photoresist layer, to transfer the pattern to the dielectric masking layer 304. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 304 compared to the material of the underlying additional ILD layer 214b. Thus, the etch operation may stop on the ILD layer 214b with minimal etching to the ILD layer 214b.

Another etch operation is performed to etch through the portion of the additional ILD layer 214b left exposed by the pattern that was transferred to the dielectric masking layer 304 to form a first recess 306. The removal of the portion of the additional ILD layer 214b to form the first recess 306 exposes part of the additional ILD layer 214b in the space between edges of the first insulator layer 236a and first top electrode layer 238a and edges of the second insulator layer 236b and second top electrode layer 238b. The etch operation may be continued to etch the part of the additional ILD layer 214b in the space and an underlying portion of the ILD layer 214a to form the second recess 308. The etch operation may include, for example, a gas-based etch operation in which a different type of etchant is used, as compared to the etchant that was used to transfer the pattern to the dielectric masking layer 304. Thus, the semiconductor device 200 may be transferred from a first etch tool (in which the pattern was transferred to the dielectric masking layer 304) to a second etch tool (in which the ILD layers 214b and 214a are etched) using a wafer/die transport tool to reduce the likelihood of cross-contamination between the first and second etch tools. Alternatively, an etch tool that has multiple processing chambers (e.g., a cluster tool) may be used, and the semiconductor device 200 may be transferred between processing chambers of the etch tool for etching using different types of etchants.

The first recess 306 has the dimension D3 in the x-direction (e.g., width), and the second recess 308 has the dimension D4 in the x-direction (e.g., width) that is smaller than the dimension D3. The second recess 308 having the smaller dimension D4 is due to the first and second top electrode layers 238a and 238b functioning as an etch mask during etching of the underlying exposed portion of the ILD layer 214a to form the second recess 308. In some implementations, the dimension D4 is equal to or approximately equal to the dimension D5. The second recess 308 exposes a portion of the top surface of the metallization structure 248.

The gas-based etchant that is used to etch the ILD layers 214b and 214a to form the first recess 306 and the second recess 308 may include a fluorine-based gas etchant that has a higher etch rate for the dielectric materials of the ILD layers 214b and 214a, compared to the etch rate of the dielectric masking layer 304. This enables the ILD layers 214b and 214a to be etched with minimal etching to the dielectric masking layer 304 (and thus, minimal to no increase in the width or critical dimension at the top of the first recess 306). The fluorine-based etchant may include a carbon fluoride-based (CFx) gas etchant such as a carbon tetrafluoride (CF4) gas etchant.

As shown in FIG. 3J, the first contact structure 244 may be formed in the first recess 306, and the second contact structure 246 may be formed in the second recess 308. A deposition tool may be used to deposit the material of the first contact structure 244 and of the second contact structure 246 using a CVD technique, a PVD technique, an ALD technique, an electroplating technique, and/or another suitable deposition technique. The first contact structure 244 and the second contact structure 246 may be deposited in one or more deposition operations. In some implementations, a seed layer is first deposited, and the first contact structure 244 and/or the second contact structure 246 are deposited on the seed layer. In some implementations, a planarization tool is used to perform a planarization operation (e.g., a CMP operation) to planarize the first contact structure 244 after the first contact structure 244 is deposited. In some implementations, a dimension D3 of the first contact structure 244 is equal to or approximately equal to the width of the first recess 306 (the width of the first recess 306 is also referred to as dimension D3). In some implementations, a dimension D4 of the second contact structure 246 is equal to or approximately equal to the width of the second recess 308 (the width of the second recess 308 is also referred to as dimension D4).

As further shown in FIG. 3J, layer 218f of the interconnect layer 204 of the semiconductor device 200 is formed above the layer 220e of the interconnect layer 204, including above the first and second trench capacitor structures 228 and 230, and above the first contact structure 244. The layer 218f includes another ILD layer 214c and another ESL 216. The layer 218f of the interconnect layer 204 may be formed in a similar manner as the layers 218a-218e of the interconnect layer 204, as described in connection with FIG. 3C.

As shown in FIG. 3K, a dielectric masking layer 310 may be formed on the additional ILD layer 214c. The dielectric masking layer 304 may include a silicon oxynitride material (SiON) and/or another suitable dielectric material.

A deposition tool may be used to deposit the dielectric masking layer 310 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 304 after the dielectric masking layer 310 is deposited.

A photoresist layer may be formed above the dielectric masking layer 310, and a pattern may be formed in the photoresist layer. Similar to the patterning of the dielectric masking layer 304 described in connection with FIG. 3I, an etch tool may be used to etch the dielectric masking layer 310 based on a pattern in a photoresist layer, to transfer the pattern to the dielectric masking layer 310. Another etch operation is performed to etch through a portion of the additional ILD layer 214c and the underlying ESL 216 left exposed by the pattern that was transferred to the dielectric masking layer 310 to form a recess 312 exposing a top surface of the first contact structure 244.

As shown in FIG. 3L, the top metallization structure 242 may be formed in the recess 312. A deposition tool may be used to deposit the material of the top metallization structure 242 using a CVD technique, a PVD technique, an ALD technique, an electroplating technique, and/or another suitable deposition technique. The top metallization structure 242 may be deposited in one or more deposition operations. In some implementations, a seed layer is first deposited, and the top metallization structure 242 is deposited on the seed layer. In some implementations, a planarization tool is used to perform a planarization operation (e.g., a CMP operation) to planarize the top metallization structure 242 after the top metallization structure 242 is deposited.

As indicated above, FIGS. 3A-3L are provided as an example. Other examples may differ from what is described with regard to FIGS. 3A-3L.

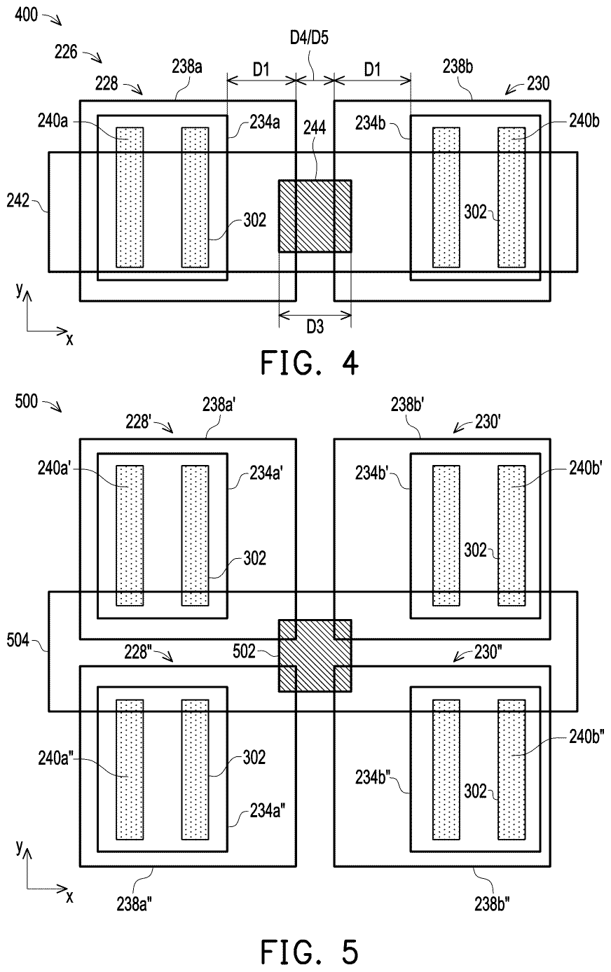

FIG. 4 is a schematic top-view diagram of an example implementation 400 of a semiconductor structure 226 including first and second trench capacitor structures 228 and 230 described herein. The first and second trench capacitor structures 228 and 230 are arranged side-by-side in the x-direction with the first contact structure 244 overlapping end portions of the first top electrode layer 238a and the second top electrode layer 238b. An edge of the first bottom electrode layer 234a is spaced apart from an edge of the first top electrode layer 238a by the dimension D1 in the x-direction, and an edge of the second bottom electrode layer 234b is spaced apart from an edge of the second top electrode layer 238b by the dimension D1 in the x-direction. In some implementations, the spacing between the edge of the first bottom electrode layer 234a and the edge of the first top electrode layer 238a may differ from the spacing between the edge of the second bottom electrode layer 234b and the edge of the second top electrode layer 238b.

The edge of the first top electrode layer 238a is spaced apart from the edge of the second top electrode layer 238b by the dimension D5 which, as noted herein, may be equal to the dimension D4 in the x-direction (e.g., width) of the second contact structure 246. The dimension D3 in the x-direction (e.g., width) of the first contact structure 244 is greater than the dimensions D4 and D5 in the x-direction.

The first trench capacitor structure 228 includes two trenches 302 filled with the first dielectric fill layer 240a, and the second trench capacitor structure 230 includes two trenches 302 filled with the second dielectric fill layer 240b. The top metallization structure 242 extends over the first and second trench capacitor structures 228 and 230, and over the first contact structure 244. In some implementations, the first and second trench capacitor structures may have the same arrangement of trenches and MIM structures as with the first and second trench capacitor structures 228 and 230. Alternatively, first and second trench capacitor structures that are commonly connected by their top electrode layers to the same contact structure may have a different arrangement of trenches and MIM structures from each other. For example, in some implementations, the quantity and/or sizes of trenches in the first capacitor structure may differ from the quantity and/or sizes of trenches in the second trench capacitor structure. Additionally and/or alternatively, the quantities and/or compositions of the electrode layers and/or insulator layers in the first and second trench capacitor structures may be different from each other.

As indicated above, FIG. 4 is provided as an example. Other examples may differ from what is described with regard to FIG. 4.

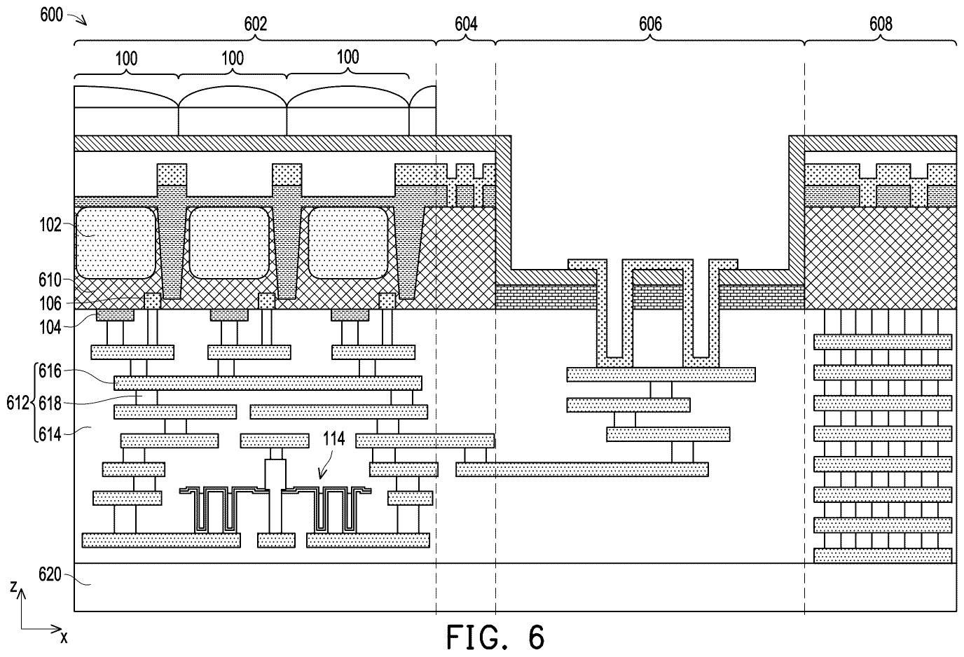

FIG. 5 is a schematic top-view diagram of an example implementation 500 of a semiconductor structure including four trench capacitor structures 228′, 228″, 230′, and 230″. Similar to the trench capacitor structures 228 and 230, each of the four trench capacitor structures 228′, 228″, 230′, and 230″ includes an MIM structure including a bottom electrode layer, an insulator layer, and a top electrode layer in a plurality of trenches 302. For example, FIG. 5 illustrates a first bottom electrode layer 234a′, a first top electrode layer 238a′, and a first dielectric fill layer 240a′ of a first trench capacitor structure 228′, a second bottom electrode layer 234b′, a second top electrode layer 238b′, and a second dielectric fill layer 240b′ of a second trench capacitor structure 230′, a third bottom electrode layer 234a″, a third top electrode layer 238a″, and a third dielectric fill layer 240a″ of a third trench capacitor structure 228″, and a fourth bottom electrode layer 234b″, a fourth top electrode layer 238b″, and a fourth dielectric fill layer 240b″ of a fourth trench capacitor structure 230″. The trench capacitor structures 228′ and 228″ are similar to the trench capacitor structure 228, and the trench capacitor structures 230′ and 230″ are similar to the trench capacitor structure 230, except that four adjacent trench capacitor structures 228′, 228″, 230′, and 230″ are commonly connected by their top electrode layers 238a′, 238a″, 238b′, and 238b″ to a contact structure 502, and the location where the contact structure 502 overlaps the top electrode layers 238a′, 238a″, 238b′, and 238b″ is different from that for the example implementations where there are two adjacent trench capacitor structures 228 and 230 commonly connected to a contact structure 244.

The first and second trench capacitor structures 228′ and 230′, and the third and fourth trench capacitor structures 228″ and 230″ are arranged side-by-side in the x-direction with the contact structure 502 overlapping corner portions of the first top electrode layer 238a′, the second top electrode layer 238b′, the third top electrode layer 238a″, and the fourth top electrode layer 238b″. The first and third trench capacitor structures 228′ and 228″, and the second and fourth trench capacitor structures 230′ and 230″ are arranged next to each other in the y-direction with the contact structure 502 overlapping corner portions of the first top electrode layer 238a′, the second top electrode layer 238b′, the third top electrode layer 238a″, and the fourth top electrode layer 238b″.

Similar to the semiconductor device 200 and example implementation 400, in the example implementation 500, edges of the bottom electrode layers 234a′, 234a″, 234b′, and 234b″ of each trench capacitor structure 228′, 228″, 230′, and 230″ are spaced apart from edges of the top electrode layers 238a′, 238a″, 238b′, and 238b″ of each trench capacitor structure 228′, 228″, 230′, and 230″ and the stepped structures of the stacked arrangements of the MIM structures of the trench capacitor structures 228′, 228″, 230′, and 230″ are similar to the stepped structures of the stacked arrangements of the MIM structures of the trench capacitor structures 228 and 230.

An edge of the first top electrode layer 238a′ is spaced apart from an edge of the second top electrode layer 238b′ in the x-direction, an edge of the third top electrode layer 238a″ is spaced apart from an edge of the fourth top electrode layer 238b″ in the x-direction, an edge of the first top electrode layer 238a′ is spaced apart from an edge of the third top electrode layer 238a″ in the y-direction, and an edge of the second top electrode layer 238b′ is spaced apart from an edge of the fourth top electrode layer 238b″ in the y-direction. A top metallization structure 504 similar to the top metallization structure 242 extends over the trench capacitor structures 228′, 228″, 230′, and 230″, and over the contact structure 502.

As indicated above, FIG. 5 is provided as an example. Other examples may differ from what is described with regard to FIG. 5.

FIG. 6 is a diagram of an example semiconductor device 600 described herein. The semiconductor device 600 may include an example of a three-dimensional image sensor (e.g., a 3D CMOS image sensor). The semiconductor device 600 may be configured to be deployed in various implementations, such as digital cameras, video recorders, night-vision cameras, automotive sensors and cameras, and/or other types of light-sensing implementations.

As shown in FIG. 6, the semiconductor device 600 may include a pixel sensor array 602. The semiconductor device 600 may further include a black level correction (BLC) region 604, a bonding pad region 606, and/or a seal ring region 608, among other examples. The pixel sensor array 602 may include a plurality of pixel sensors 100 arranged in an array. The pixel sensors 100 may be configured to sense incident light and convert photons of the incident light to a photocurrent. The pixel sensors 100 may be included in a device layer 610 of the semiconductor device 600. The pixel sensors 100 may each include one or more photodiodes 102 that are configured to generate a photocurrent based on photons of incident light. The pixel sensors 100 may further include a floating diffusion node 106 in the device layer 610 that is configured to temporarily store the photocurrent generated by an associated pixel sensor 100, and may each include a transfer gate 104 that is configured to control the flow of photocurrent from a photodiode 102 to a floating diffusion node 106. The pixel sensors 100 may be formed by one or more semiconductor processing tools using various semiconductor processing techniques, such as photolithography, etching, deposition, CMP, and/or ion implantation, among other examples.

The BLC region 604 includes a metal shielding layer over a portion of the device layer 610 so that a baseline measurement of current in the device layer 610 in the BLC region 604 can be performed to determine the dark current (e.g., the current in the device layer 610 that is generated from sources other than incident light, such as heat) of the pixel sensor array 602, so that the black level of the pixel sensor array 602 can be adjusted to compensate for the dark current. The bonding pad region 606 may include one or more conductive bonding pads (or e-pads) and/or metallization layers through which electrical connections between the semiconductor device 600 and outside devices and/or external packaging may be established. The seal ring region 608 may include an arrangement of metallization structures and interconnect structures to provide structural rigidity for the semiconductor device 600 and to protect the semiconductor device 600 from ingress of humidity and other contaminants.

As further shown in FIG. 6, the semiconductor device 600 may include an interconnect layer 612 under the device layer 610. The interconnect layer 612 may include a dielectric region 614 that includes one or more dielectric layers (e.g., ILD layers, intermetal dielectric (IMD) layers, ESLs) and an arrangement of metallization structures 616 and interconnect structures 618 in the dielectric region 614. A passivation layer 620 may be included under the interconnect layer 612.

As further shown in FIG. 6, one or more overflow capacitors 114 may be included in the interconnect layer 612. The overflow capacitor(s) 114 may be structurally implemented as the first trench capacitor structure 228 and/or the second trench capacitor structure 230 illustrated and described herein. An overflow capacitor 114 may be electrically coupled to a floating diffusion node 106 of a pixel sensor 100 and may be configured to store overflow photocurrent from the floating diffusion node 106.

As indicated above, FIG. 6 is provided as an example. Other examples may differ from what is described with regard to FIG. 6.

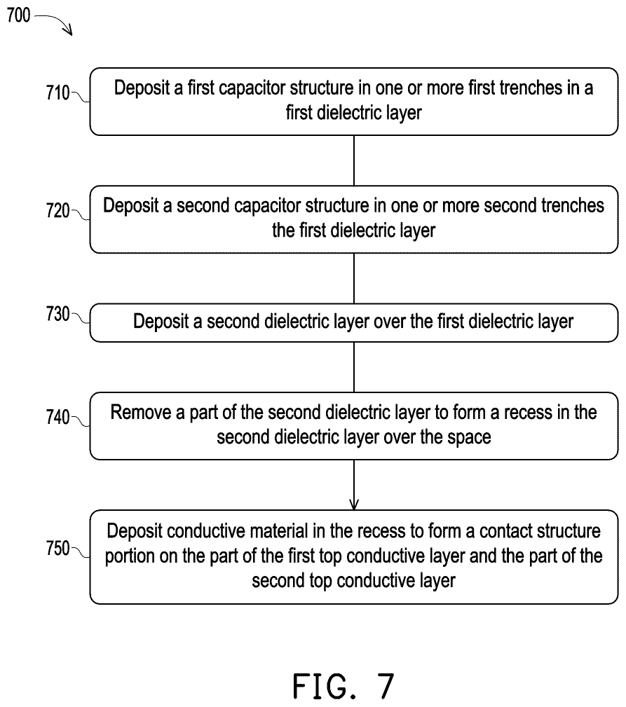

FIG. 7 is a flowchart of an example process 700 associated with a method of forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include depositing a first capacitor structure in one or more first trenches in a first dielectric layer (block 710). For example, one or more semiconductor processing tools may be used to deposit a first capacitor structure (e.g., first trench capacitor structure 228) in one or more first trenches (e.g., trenches 302) in a first dielectric layer (e.g., ILD layer 214a), as described herein. In some implementations, the first capacitor structure includes a first stacked arrangement of a first bottom conductive layer (e.g., first bottom electrode layer 234a), a first insulator layer (e.g., first insulator layer 236a) on the first bottom conductive layer, and a first top conductive layer (e.g., first top electrode layer 238a) on the first insulator layer.

As further shown in FIG. 7, process 700 may include depositing a second capacitor structure in one or more second trenches in the first dielectric layer (block 720). For example, one or more semiconductor processing tools may be used to deposit a second capacitor structure (e.g., second trench capacitor structure 230) in one or more second trenches (e.g., trenches 302) in the first dielectric layer, as described herein. In some implementations, the second capacitor structure is adjacent to the first capacitor structure. In some implementations, the second capacitor structure includes a second stacked arrangement of a second bottom conductive layer (e.g., second bottom electrode layer 234b), a second insulator layer (e.g., second insulator layer 236b) on the second bottom conductive layer, and a second top conductive layer (e.g., second top electrode layer 238b) on the second insulator layer. In some implementations, a part of the first stacked arrangement and a part of the second stacked arrangement are deposited on the first dielectric layer between the first capacitor structure and the second capacitor structure. In some implementations, the part of the first stacked arrangement and the part of the second stacked arrangement are separated from each other by a space.

As further shown in FIG. 7, process 700 may include depositing a second dielectric layer over the first dielectric layer (block 730). For example, one or more semiconductor processing tools may be used to deposit a second dielectric layer (e.g., ILD layer 214b) over the first dielectric layer, as described herein.

As further shown in FIG. 7, process 700 may include removing a part of the second dielectric layer to form a recess in the second dielectric layer over the space (block 740). For example, one or more semiconductor processing tools may be used to remove a part of the second dielectric layer to form a recess (e.g., first recess 306) in the second dielectric layer over the space, as described herein. In some implementations, the recess exposes a part of the first top conductive layer and a part of the second top conductive layer.

As further shown in FIG. 7, process 700 may include depositing conductive material in the recess to form a contact structure portion on the part of the first top conductive layer and the part of the second top conductive layer (block 750). For example, one or more semiconductor processing tools may be used to deposit conductive material in the recess to form a contact structure portion (e.g., first contact structure 244) on the part of the first top conductive layer and the part of the second top conductive layer, as described herein.

Process 700 may include additional implementations, such as any single implementation or any combination of implementations described below and/or in connection with one or more other processes described elsewhere herein.

In a first implementation, process 700 includes removing an additional part of the second dielectric layer in the space and a part of the first dielectric layer under the space to form an additional recess (e.g., second recess 308) in the second dielectric layer and in the first dielectric layer, where a width (e.g., dimension D4) of the additional recess is smaller than a width (e.g., dimension D3) of the recess. In removing the additional part of the second dielectric layer and the part of the first dielectric layer, the part of the first top conductive layer and the part of the second top conductive layer may be used as a mask.

In a second implementation, alone or in combination with the first implementation, the conductive material is further deposited in the additional recess to form an additional contact structure portion (e.g., second contact structure 246) on a metallization structure (e.g., metallization structure 248).

In a third implementation, alone or in combination with one or more of the first and second implementations, the part of the first stacked arrangement on the first dielectric layer includes a first portion including the first insulator layer on the first bottom conductive layer and the first top conductive layer on the first insulator layer, where the first bottom conductive layer is in contact with the first dielectric layer, and a second portion including the first top conductive layer on the first insulator layer, where the first insulator layer is in contact with the first dielectric layer.

In a fourth implementation, alone or in combination with one or more of the first through third implementations, the part of the second stacked arrangement on the first dielectric layer includes a first portion including the second insulator layer on the second bottom conductive layer and the second top conductive layer on the second insulator layer, where the second bottom conductive layer is in contact with the first dielectric layer, and a second portion including the second top conductive layer on the second insulator layer, where the second insulator layer is in contact with the first dielectric layer.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, the top electrode layers of multiple capacitor structures are commonly connected to the same interconnect structure (e.g., via) for the supply of voltage to each top electrode layer. The commonly connected top electrode layers require a smaller quantity of metallization structures and interconnect structures for signal routing, which occupy a smaller area of a semiconductor device in comparison to metallization structures and interconnect structures for individually connected top electrode layers. As a result, larger MIM capacitor structures may be formed, resulting in larger capacitor storage capacity, and increased device performance.

As described in greater detail above, some implementations described herein provide a semiconductor structure. The semiconductor structure includes a first capacitor structure, where the first capacitor structure includes a first bottom electrode layer in a first trench, a first top electrode layer in the first trench, and a first insulator layer in the first trench and disposed between the first bottom electrode layer and the first top electrode layer. The semiconductor structure includes a second capacitor structure disposed adjacent to the first capacitor structure. The second capacitor structure includes a second bottom electrode layer in a second trench, a second top electrode layer in the second trench, and a second insulator layer in the second trench and disposed between the second bottom electrode layer and the second top electrode layer. A portion of the first top electrode layer is disposed over a first part of a dielectric layer between the first trench and the second trench. A portion of the second top electrode layer is disposed over a second part of a dielectric layer between the first trench and the second trench. The semiconductor structure includes a contact structure on the first top electrode layer and the second top electrode layer.

As described in greater detail above, some implementations described herein provide a method. The method includes depositing a first capacitor structure in one or more first trenches in a first dielectric layer, where the first capacitor structure includes a first stacked arrangement of a first bottom conductive layer, a first insulator layer on the first bottom conductive layer, and a first top conductive layer on the first insulator layer. The method includes depositing a second capacitor structure in one or more second trenches the first dielectric layer, where the second capacitor structure is adjacent to the first capacitor structure, where the second capacitor structure includes a second stacked arrangement of a second bottom conductive layer, a second insulator layer on the second bottom conductive layer, and a second top conductive layer on the second insulator layer, where a part of the first stacked arrangement and a part of the second stacked arrangement are deposited on the first dielectric layer between the first capacitor structure and the second capacitor structure, and where the part of the first stacked arrangement and the part of the second stacked arrangement are separated from each other by a space. The method includes depositing a second dielectric layer over the first dielectric layer. The method includes removing a part of the second dielectric layer to form a recess in the second dielectric layer over the space, where the recess exposes a part of the first top conductive layer and a part of the second top conductive layer. The method includes depositing conductive material in the recess to form a contact structure portion on the part of the first top conductive layer and the part of the second top conductive layer.

As described in greater detail above, some implementations described herein provide a semiconductor device. The semiconductor device includes an interconnect structure disposed over a plurality of transistors, where the interconnect structure includes a plurality of dielectric layers interleaved by a plurality of etch stop layers and the interconnect structure includes a plurality of metal lines disposed in the plurality of dielectric layers, and where a thickness of a bottommost one of the plurality of dielectric layers is less than a thickness of at least one of the plurality of dielectric layers above the bottommost one of the plurality of dielectric layers. The semiconductor device includes a plurality of capacitor structures in one or more of the plurality of dielectric layers of the interconnect structure, where each capacitor structure of the plurality of capacitor structures includes a bottom electrode layer, a top electrode layer, and an insulator layer between the top electrode layer and the bottom electrode layer. The semiconductor device includes a contact structure disposed on top electrode layers of at least two adjacent capacitor structures, where the contact structure connects the top electrode layers of the at least two adjacent capacitor structures to a same metal line of the plurality of metal lines.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first capacitor structure,
wherein the first capacitor structure comprises:
a first bottom electrode layer in a first trench;
a first top electrode layer in the first trench; and
a first insulator layer in the first trench and disposed between the first bottom electrode layer and the first top electrode layer;
a second capacitor structure disposed adjacent to the first capacitor structure,
wherein the second capacitor structure comprises:
a second bottom electrode layer in a second trench;
a second top electrode layer in the second trench; and
a second insulator layer in the second trench and disposed between the second bottom electrode layer and the second top electrode layer,
wherein a portion of the first top electrode layer is disposed over a first part of a dielectric layer between the first trench and the second trench,
wherein a portion of the second top electrode layer is disposed over a second part of a dielectric layer between the first trench and the second trench; and
a contact structure on the first top electrode layer and the second top electrode layer.

2. The semiconductor structure of claim 1, wherein the portion of the first top electrode layer is spaced apart from the portion of the second top electrode layer.

3. The semiconductor structure of claim 2, further comprising an additional contact structure disposed under the contact structure,
wherein the additional contact structure is disposed in a space between the portion of the first top electrode layer and the portion of the second top electrode layer.

4. The semiconductor structure of claim 3, wherein a width of the additional contact structure is smaller than a width of the contact structure.

5. The semiconductor structure of claim 1, wherein the first bottom electrode layer is disposed on a first bottom contact located under the first trench, and
wherein the second bottom electrode layer is disposed on a second bottom contact located under the second trench.

6. The semiconductor structure of claim 1, wherein a portion of the first bottom electrode layer is disposed over the first part of the dielectric layer between the first trench and the second trench, and
wherein an edge of the portion of the first top electrode layer is closer to the second capacitor structure than an edge of the portion of the first bottom electrode layer.

7. The semiconductor structure of claim 1, wherein a portion of the first bottom electrode layer is disposed over the first part of the dielectric layer between the first trench and the second trench, and
wherein a dimension of the portion of the first top electrode layer along a direction toward the second capacitor structure is larger than a dimension of the portion of the first bottom electrode layer along the direction toward the second capacitor structure.

8. The semiconductor structure of claim 1, wherein the portion of the first top electrode layer and the portion of the second top electrode layer each comprise a stepped structure.

9. A method, comprising:
depositing a first capacitor structure in one or more first trenches in a first dielectric layer,
wherein the first capacitor structure comprises a first stacked arrangement of a first bottom conductive layer, a first insulator layer on the first bottom conductive layer, and a first top conductive layer on the first insulator layer;
depositing a second capacitor structure in one or more second trenches the first dielectric layer,
wherein the second capacitor structure is adjacent to the first capacitor structure,
wherein the second capacitor structure comprises a second stacked arrangement of a second bottom conductive layer, a second insulator layer on the second bottom conductive layer, and a second top conductive layer on the second insulator layer,
wherein a part of the first stacked arrangement and a part of the second stacked arrangement are deposited on the first dielectric layer between the first capacitor structure and the second capacitor structure, and
wherein the part of the first stacked arrangement and the part of the second stacked arrangement are separated from each other by a space;
depositing a second dielectric layer over the first dielectric layer; removing a part of the second dielectric layer to form a recess in the second dielectric layer over the space,
wherein the recess exposes a part of the first top conductive layer and a part of the second top conductive layer; and
depositing conductive material in the recess to form a contact structure portion on the part of the first top conductive layer and the part of the second top conductive layer.

10. The method of claim 9, further comprising removing an additional part of the second dielectric layer in the space and a part of the first dielectric layer under the space to form an additional recess in the second dielectric layer and in the first dielectric layer,
wherein a width of the additional recess is smaller than a width of the recess.

11. The method of claim 10, wherein, in removing the additional part of the second dielectric layer and the part of the first dielectric layer, the part of the first top conductive layer and the part of the second top conductive layer are used as a mask.

12. The method of claim 10, wherein the conductive material is further deposited in the additional recess to form an additional contact structure portion on a metallization structure.

13. The method of claim 9, wherein the part of the first stacked arrangement on the first dielectric layer comprises:
a first portion including the first insulator layer on the first bottom conductive layer and the first top conductive layer on the first insulator layer,
wherein the first bottom conductive layer is in contact with the first dielectric layer; and
a second portion including the first top conductive layer on the first insulator layer,
wherein the first insulator layer is in contact with the first dielectric layer.

14. The method of claim 9, wherein the part of the second stacked arrangement on the first dielectric layer comprises:
a first portion including the second insulator layer on the second bottom conductive layer and the second top conductive layer on the second insulator layer,
wherein the second bottom conductive layer is in contact with the first dielectric layer; and
a second portion including the second top conductive layer on the second insulator layer,
wherein the second insulator layer is in contact with the first dielectric layer.

15. A semiconductor device, comprising:
an interconnect structure disposed over a plurality of transistors,
wherein the interconnect structure comprises a plurality of dielectric layers interleaved by a plurality of etch stop layers and the interconnect structure comprises a plurality of metal lines disposed in the plurality of dielectric layers,
wherein a thickness of a bottommost one of the plurality of dielectric layers is less than a thickness of at least one of the plurality of dielectric layers above the bottommost one of the plurality of dielectric layers;
a plurality of capacitor structures in one or more of the plurality of dielectric layers of the interconnect structure,
wherein each capacitor structure of the plurality of capacitor structures comprises:
a bottom electrode layer;
a top electrode layer; and
an insulator layer between the top electrode layer and the bottom electrode layer; and
a contact structure disposed on top electrode layers of at least two adjacent capacitor structures,
wherein the contact structure connects the top electrode layers of the at least two adjacent capacitor structures to a same metal line of the plurality of metal lines.

16. The semiconductor device of claim 15, wherein the contact structure is disposed between the at least two adjacent capacitor structures.

17. The semiconductor device of claim 15, further comprising an additional contact structure extending from the contact structure,
wherein the additional contact structure is disposed in a space between the top electrode layers of the at least two adjacent capacitor structures, and
wherein a width of the additional contact structure is approximately equal to a width of the space between the top electrode layers of the at least two adjacent capacitor structures.

18. The semiconductor device of claim 17, wherein the additional contact structure is disposed on an additional metal line of the plurality of metal lines.

19. The semiconductor device of claim 15, wherein the bottom electrode layer of each capacitor structure of the plurality of capacitor structures is disposed on a different metal line of the plurality of metal lines.

20. The semiconductor device of claim 15, wherein the plurality of transistors comprises transistors of one or more pixel sensors, and
wherein the plurality of capacitor structures are connected to the plurality of transistors.
